(19) United States
(12) Patent Application Publication
(10) Pub. No.: US 2026/0293637 A1
(43) Pub. Date: Sep. 24, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Meng-Ying LI, Tainan City (TW); Chun-Hao CHOU, Tainan City (TW)

(21) Appl. No.: 19/086,946

(22) Filed: Mar. 21, 2025

(51) Int. Cl. H01L 21/768; H01L 23/528; H01L 23/544

(52) U.S. Cl. CPC H10W 20/095; H10W 20/435; H10W 46/00; H10W 46/301

(57) ABSTRACT

A semiconductor chip includes a plurality of exposure regions which are sequentially patterned by different reticles. For example, two or more reticles may be used to respectively pattern different portions of a semiconductor chip, resulting in a semiconductor chip with increased area in comparison to semiconductor chips manufactured with a single reticle. As a result, the semiconductor chip can incorporate various circuit functions that may be needed for high performance computing (HPC) functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

### BACKGROUND

An extreme ultraviolet (EUV) radiation source includes a collector, which includes a curved mirror that is configured to collect EUV radiation and to focus the EUV radiation toward an intermediate focus near an intermediate focus cap (IF cap) of the EUV radiation source. The EUV radiation is produced from a laser produced plasma (LPP) that is generated by exposing droplets of tin (Sn) to a carbon dioxide (CO₂) laser. The Sn droplets are generated by a droplet generator (DG) head, which provides the Sn droplets into a vacuum chamber to an irradiation site where the Sn droplets are irradiated by a focused laser beam.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example lithography system described herein.

FIGS. 2A and 2B are diagrams of an example semiconductor device described herein.

FIGS. 3A-3H are diagrams of an example implementation of forming a semiconductor device described herein.

FIG. 4 is a diagram of an example implementation of a semiconductor device described herein.

FIGS. 5A and 5B are diagrams of example implementations of semiconductor devices described herein.

FIGS. 6A and 6B are diagrams of example implementations of a semiconductor device described herein.

FIGS. 7A and 7B are diagrams of an example semiconductor device described herein.

FIG. 8 is a diagram of an example semiconductor device described herein.

FIG. 9 is a diagram of an example semiconductor device described herein.

FIG. 10 is a flowchart of an example process associated with forming a semiconductor device described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A lithography system may include a radiation source and an exposure tool. The radiation source (e.g., an EUV radiation source or another type of radiation source) may be configured to generate radiation such as EUV radiation and/or another type of electromagnetic radiation (e.g., light). An exposure tool (e.g., an EUV scanner or another type of exposure tool) may be configured to focus the radiation onto a reflective reticle (or a photomask) such that a pattern is transferred from the reticle onto a semiconductor substrate using the radiation. The radiation may reflect off of the reticle based on a pattern of the reticle. The radiation may be reflected onto the semiconductor substrate such that the pattern of the reticle is transferred to the semiconductor substrate.

High performance computing (HPC) may include processing large amounts of data at high speed to perform complex calculations. HPC may require specialized computer chips capable of performing multiple functions to perform parallel processing of data. Each specialized computer chip may be integrated with multiple devices and contact structures that would otherwise be found on multiple non-specialized chips. As a result, the size of such specialized computer chips (e.g., “superchips”) may need to be larger than the non-specialized chips to include the devices and/or contact structures that may be required to perform HPC functions.

In some cases, the size of a semiconductor chip (e.g., semiconductor die) may be dependent on the size of a reticle used to pattern the devices and/or contact structures onto the chip. As a result, chip size may be limited by reticle size, which may prevent specialized computer chips from having a requisite device density to execute HPC functions. Accordingly, multiple specialized computer chips may need to be interconnected in an HPC device, which may reduce HPC performance and/or increase risk of failure if the connections between separate chips fail. In addition, external connections and required spacing between the multiple specialized computer chips may increase HPC device size.

In some implementations, in order to address reticle-based chip size limitations, a semiconductor chip includes a plurality of exposure regions which are sequentially patterned by different reticles. For example, two or more reticles may be used to respectively pattern different portions of a semiconductor chip, resulting in a semiconductor chip with increased area in comparison to semiconductor chips manufactured with a single reticle. As a result, the semiconductor chip can incorporate various circuit functions that may be needed for HPC functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

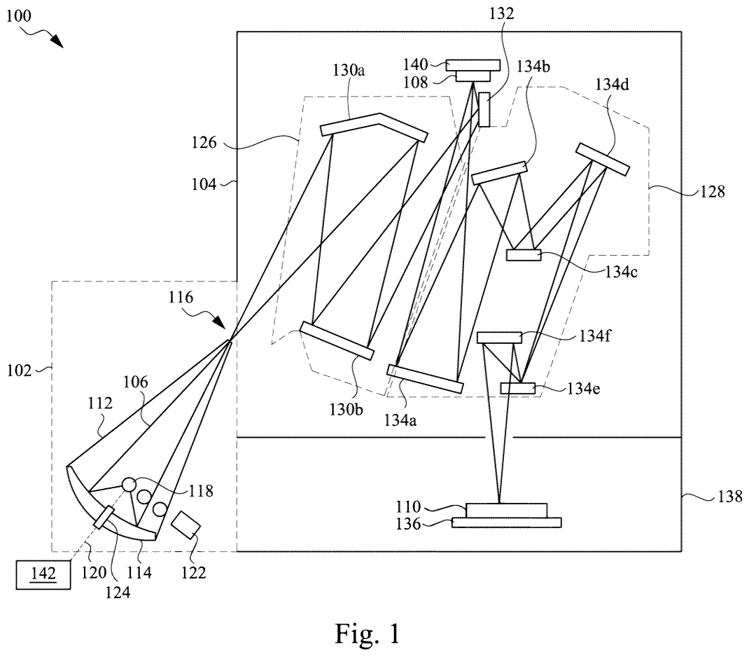

FIG. 1 is a diagram of an embodiment of a lithography system 100 described herein. The lithography system 100 includes an extreme ultraviolet (EUV) lithography system or another type of lithography system that is configured to transfer a pattern to a semiconductor substrate using mirror-based optics. The lithography system 100 may be configured for use in a semiconductor processing environment such as a semiconductor foundry or a semiconductor fabrication facility.

As shown in FIG. 1, the lithography system 100 includes the radiation source 102 and an exposure tool 104. The radiation source 102 (e.g., an EUV radiation source or another type of radiation source) is configured to generate radiation 106 such as EUV radiation and/or another type of electromagnetic radiation (e.g., light). The exposure tool 104 (e.g., an EUV scanner or another type of exposure tool) is configured to focus the radiation 106 onto a reflective reticle 108 (or a photomask) such that a pattern is transferred from the reticle 108 onto a semiconductor substrate 110 using the radiation 106.

The radiation source 102 includes a vessel 112 and a collector 114 in the vessel 112. The collector 114, includes a curved mirror that is configured to collect the radiation 106 generated by the radiation source 102 and to focus the radiation 106 toward an intermediate focus 116. The radiation 106 is produced from a plasma that is generated from droplets 118 (e.g., tin (Sn) droplets or another type of droplets) being exposed to a laser beam 120. The droplets 118 are provided across the front of the collector 114 by a droplet generator (DG) head 122. The DG head 122 is pressurized to provide a fine and controlled output of the droplets 118.

A laser source, such as a pulse carbon dioxide (CO₂) laser, generates the laser beam 120. The laser beam 120 is provided (e.g., by a beam delivery system to a focus lens) such that the laser beam 120 is focused through a window 124 of the collector 114. The laser beam 120 is focused onto the droplets 118 which generates the plasma. The plasma produces a plasma emission, some of which is the radiation 106. The laser beam 120 is pulsed at a timing that is synchronized with the flow of the droplets 118 from the DG head 122.

The exposure tool 104 includes an illuminator 126 and a projection optics box (POB) 128. The illuminator 126 includes a plurality of reflective mirrors that are configured to focus and/or direct the radiation 106 onto the reticle 108 so as to illuminate the pattern on the reticle 108. The plurality of mirrors include, for example, a mirror 130a and a mirror 130b. The mirror 130a includes a field facet mirror (FFM) or another type of mirror that includes a plurality of field facets. The mirror 130b includes a pupil facet mirror (PFM) or another type of mirror that also includes a plurality of pupil facets. The facets of the mirrors 130a and 130b are arranged to focus, polarize, and/or otherwise tune the radiation 106 from the radiation source 102 to increase the uniformity of the radiation 106 and/or to increase particular types of radiation components (e.g., transverse electric (TE) polarized radiation, transverse magnetic (TM) polarized radiation). Another mirror 132 (e.g., a relay mirror) is included to direct radiation 106 from the illuminator 126 onto the reticle 108.

The projection optics box 128 includes a plurality of mirrors that are configured to project the radiation 106 onto the semiconductor substrate 110 after the radiation 106 is modified based on the pattern of the reticle 108. The plurality of reflective mirrors include, for example, mirrors 134a-134f. In some implementations, the mirrors 134a-134f are configured to focus or reduce the radiation 106 into an exposure field, which may include one or more die areas on the semiconductor substrate 110.

The exposure tool 104 includes a wafer stage 136 (e.g., a substrate stage) configured to support the semiconductor substrate 110. Moreover, the wafer stage 136 is configured to move (or step) the semiconductor substrate 110 through a plurality of exposure fields as the radiation 106 transfers the pattern from the reticle 108 onto the semiconductor substrate 110. The wafer stage 136 is included in a bottom module 138 of the exposure tool 104. The bottom module 138 includes a removable subsystem of the exposure tool 104. The bottom module 138 may slide out of the exposure tool 104 and/or otherwise may be removed from the exposure tool 104 to enable cleaning and inspection of the wafer stage 136 and/or the components of the wafer stage 136. The bottom module 138 isolates the wafer stage 136 from other areas in the exposure tool 104 to reduce and/or minimize contamination of the semiconductor substrate 110. Moreover, the bottom module 138 may provide physical isolation for the wafer stage 136 by reducing the transfer of vibrations (e.g., vibrations in the semiconductor processing environment in which the lithography system 100 is located, vibrations in the lithography system 100 during operation of the lithography system 100) to the wafer stage 136 and, therefore, the semiconductor substrate 110. This reduces movement and/or disturbance of the semiconductor substrate 110, which reduces the likelihood that the vibrations may cause a pattern misalignment.

The exposure tool 104 also includes a reticle stage 140 that configured to support and/or secure the reticle 108. Moreover, the reticle stage 140 is configured to move or slide the reticle through the radiation 106 such that the reticle 108 is scanned by the radiation 106. In this way, a pattern that is larger than the field or beam of the radiation 106 may be transferred to the semiconductor substrate 110.

The lithography system 100 includes a laser source 142. The laser source 142 is configured to generate the laser beam 120. The laser source 142 may include a CO2-based laser source or another type of laser source. Due to the wavelength of the laser beams generated by a CO2-based laser source in an infrared (IR) region, the laser beams may be highly absorbed by tin, which enables the CO2-based laser source to achieve high power and energy for pumping tin-based plasma. In some implementations, the laser beam 120 includes a plurality of types of laser beams that the laser source 142 generates using a multi-pulse technique (or a multi-stage pumping technique), in which the laser source 142 generates a pre-pulse laser beam and main-pulse laser beam to achieve greater heating efficiency of tin (Sn)-based plasma to increase conversion efficiency.

In an example exposure operation (e.g., an EUV exposure operation), the DG head 122 provides the stream of the droplets 118 across the front of the collector 114. The laser beam 120 contacts the droplets 118, which causes a plasma to be generated. The laser source 142 generates and provides a pre-pulse laser beam toward a target material droplet in the stream of the droplets 118, and the pre-pulse laser beam is absorbed by the target material droplet. This transforms the target material droplet into disc shape or a mist. Subsequently, the laser source 142 provides a main-pulse laser beam with large intensity and energy toward the disc-shaped target material or target material mist. Here, the atoms of the target material are neutralized, and ions are generated through thermal flux and shock wave. The main-pulse laser beam pumps ions to a higher charge state, which causes the ions to radiate the radiation 106 (e.g., EUV light).

The radiation 106 is collected by the collector 114 and directed out of the vessel 112 and into the exposure tool 104 toward the mirror 130a of the illuminator 126. The mirror 130a reflects the radiation 106 onto the mirror 130b, which reflects the radiation 106 onto the mirror 132 toward the reticle 108. The radiation 106 is modified by the pattern in the reticle 108. In other words, the radiation 106 reflects off of the reticle 108 based on the pattern of the reticle 108. The reflective reticle 108 directs the radiation 106 toward the mirror 134a in the projection optics box 128, which reflects the radiation 106 onto the mirror 134b. The radiation 106 continues to be reflected and reduced in the projection optics box 128 by the mirrors 134c-134f. The mirror 134f reflects the radiation 106 onto the semiconductor substrate 110 such that the pattern of the reticle 108 is transferred to the semiconductor substrate 110. The above-described exposure operation is an example, and the lithography system 100 may operate according to other EUV techniques and radiation paths that include a greater quantity of mirrors, a lesser quantity of mirrors, and/or a different configuration of mirrors.

As indicated above, FIG. 1 is provided as an example. Other examples may differ from what is described with regard to FIG. 1.

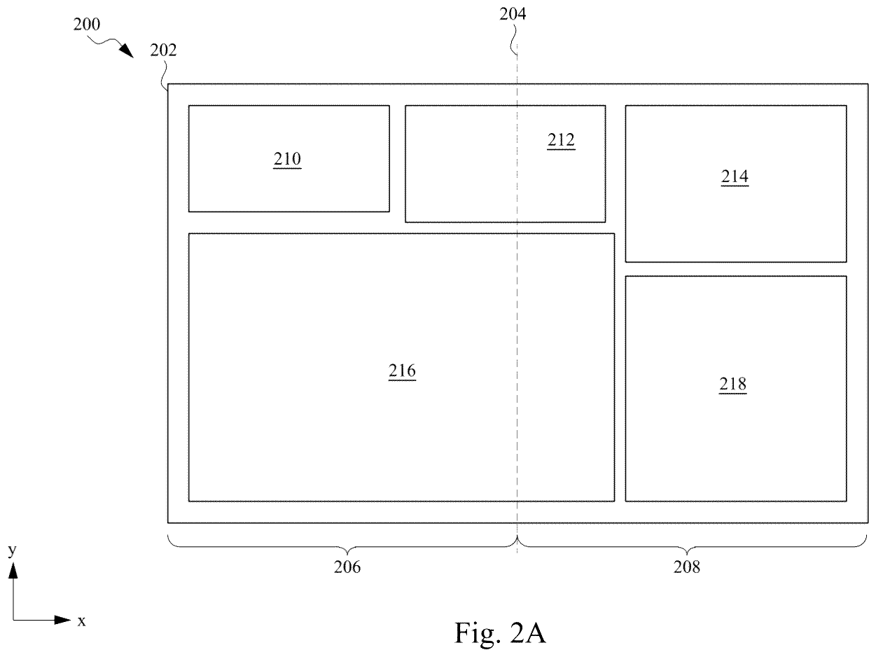

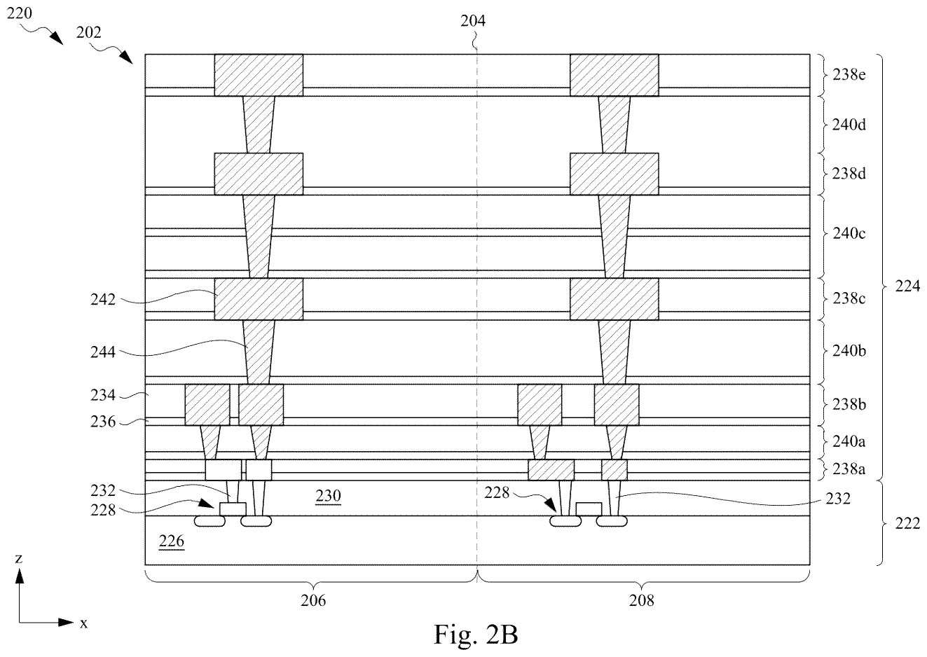

FIGS. 2A and 2B are diagrams of an example semiconductor device 200. As shown in FIG. 2A, the semiconductor device 200 includes a semiconductor chip 202. The semiconductor chip 202 may include one or more semiconductor dies with circuits configured to perform different functions. For example, the semiconductor chip 202 may include multiple dies to perform multiple HPC functions. The semiconductor chip 202 may include one or more system-on-chip (SoC) dies. An SoC die may include, for example, a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor chip 202 may include one or more of a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die.

As indicated by the dotted line 204, the semiconductor chip 202 is divided into a first exposure region 206 and a second exposure region 208. The first and second exposure regions 206 and 208 are arranged next to each other along the x-direction. The first and second exposure regions 206 and 208 abut each other. The semiconductor chip 202 may include functional areas 210, 212, 214, 216, and 218. In some implementations, the functional areas 210-218 each correspond to a die formed on the semiconductor chip 202, with each die including circuitry to perform and/or support HPC operations. For example, one or more of the functional areas 210-218 may include memory circuitry, analog circuitry, logic circuitry, radio frequency (RF) circuitry, CPU circuitry, GPU circuitry, DSP circuitry, power circuitry, ASIC circuitry, etc. In some implementations, the functional areas 210-218 are different from each other. Alternatively, one or more of the functional areas 210-218 may have the same or similar circuitry and/or correspond to the same or similar HPC functionality.

The first and second exposure regions 206 and 208 respectively correspond to first and second portions of the semiconductor chip 202 that are patterned by different reticles of a lithography system during a manufacturing process. For example, the first exposure region 206 is patterned using a first reticle, and the second exposure region 208 is patterned using a second reticle. The entire functional area 210 is in the first exposure region 206, such that each of the elements that require patterning (e.g., lithography) in the functional area 210 are patterned using the first reticle. Similarly, the entire functional area 214 and the entire functional area 218 are in the second exposure region 208, such that each of the elements that require patterning in the functional areas 214 and 218 are patterned using the second reticle. A first part of the functional area 212 is in the first exposure region 206, and a second part of the functional area 212 is in the second exposure region 208. Similarly, a first part of the functional area 216 is in the first exposure region 206, and a second part of the functional area 216 is in the second exposure region 208. The first part of the functional area 212 and the first part of the functional area 216 are patterned using the first reticle. The second part of the functional area 212 and the second part of the functional area 216 are patterned using the second reticle.

FIG. 2B illustrates a cross-section view of an example implementation 220 of a semiconductor chip 202 of the semiconductor device 200. As shown by the dotted line 204 in FIG. 2B, the semiconductor chip 202 is divided into the first exposure region 206 and the second exposure region 208. The first exposure region 206 and the second exposure region 208 are laterally adjacent to each other in the x-direction. The semiconductor chip 202 may include a device layer 222 and an interconnect layer 224 arranged in a z-direction in the semiconductor device 200 with respect to the device layer 222. For example, the interconnect layer 224 may be located above the device layer 222. As another example, the interconnect layer 224 may be located below the device layer 222.

The interconnect layer 224 may include conductive structures that are arranged to carry signals and/or provide power distribution throughout the semiconductor device 200. In some implementations, the semiconductor device 200 includes interconnect layers 224 above and below the device layer 222. A first interconnect layer 224 on a first side of the device layer 222 in the first exposure region 206 and/or the second exposure region 208 may be used for signal propagation throughout the semiconductor device 200, and a second interconnect layer 224 on an opposing second side of the device layer 222 in the first exposure region 206 and/or the second exposure region 208 may be used for power distribution in the semiconductor device 200.

The device layer 222 includes a substrate 226 of the semiconductor chip 202. The substrate 226 may correspond to a portion of a semiconductor wafer on which the semiconductor chip 202 is formed. The substrate 226 may include a silicon (Si) substrate, a substrate formed of a material including silicon, a III-V compound semiconductor material substrate such as gallium arsenide (GaAs), a silicon-on-insulator (SOI) substrate, or another type of substrate. The substrate 226 may extend in an x-direction and/or in a y-direction in the semiconductor device 200 such that the top and bottom surfaces of the substrate 226 are approximately orthogonal to the z-direction in the semiconductor device 200.

Integrated circuit devices 228 may be included in and/or on the substrate 226 in the device layer 222 in both the first exposure region 206 and the second exposure region 208 of the semiconductor chip 202. The integrated circuit devices 228 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

A front end transistor structure may include a plurality of source/drain regions, which may correspond to doped regions of the substrate 226, separated by a channel region in the substrate 226. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 230 is included over the substrate 226. The dielectric layer 230 includes an interlayer dielectric (ILD) layer, an etch stop layer (ESL), and/or another type of dielectric layer. The dielectric layer 230 includes dielectric material(s) that enable various portions of the substrate 226 and/or the integrated circuit devices 228 to be selectively etched or protected from etching, and/or to electrically isolate the integrated circuit devices 228 in the device layer 222. The dielectric layer 230 includes a silicon nitride (SiₓN_{y}), an oxide (e.g., a silicon oxide (SiOₓ) and/or another oxide material), and/or another type of dielectric material. The dielectric layer 230 may extend in the x-direction and/or in the y-direction in the semiconductor device 200. Contacts 232 (e.g., source/drain contacts, gate contacts) may extend through the dielectric layer 230 and between the integrated circuit devices 228 and the interconnect layer 224. The contacts may electrically connect the integrated circuit devices 228 to the interconnect layer 224. The contacts 232 may include vias, plugs, and/or another type of elongated electrically conductive structures. The contacts 232 may include tungsten (W), cobalt (Co), ruthenium (Ru), titanium (Ti), aluminum (Al), and/or gold (Au), among other electrically conductive materials.

The interconnect layer 224 includes a plurality of dielectric layers (e.g., back end dielectric layers) that are arranged in a direction (e.g., the z-direction) that is approximately perpendicular to the top surface of the substrate 226. The dielectric layers may include ILD layers 234 and ESLs 236 that are arranged in an alternating manner in the z-direction. The ILD layers 234 and the ESLs 236 may extend in the x-direction and/or in the y-direction in the semiconductor device 200.

The ILD layers 234 may each include a low dielectric constant (low-k) oxide material such as silicon oxide (SiOₓ) or undoped silicate glass (USG). Additionally and/or alternatively, the ILD layers 234 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 234 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 236 may each include a silicon nitride (SiₓN_{y}), silicon carbide (SiC), silicon oxynitride (SiON), and/or another suitable dielectric material. In some implementations, an ILD layer 234 and an ESL 236 include different dielectric materials to provide etch selectivity to enable various structures to be formed in the interconnect layer 224. For example, the ILD layers 234 may each include a low-k dielectric material such as USG, and the ESLs 236 may each include a high-k dielectric material such as silicon nitride (SiₓN_{y}) or silicon carbide (SiC). Additionally and/or alternatively, two or more ESLs 236 may include different materials. For example, one or more first ESLs 236 may include silicon nitride (SiₓN_{y}), and one or more second ESLs 236 may include silicon carbide (SiC).

The interconnect layer 224 includes a plurality of conductive structures that are arranged in a plurality of layers. The conductive structures may be electrically coupled and/or physically coupled with one or more of the integrated circuit devices 228 in the device layer 222. The conductive structures provide electrical routing that enables signals and/or power to be provided to and/or from the integrated circuit devices 228.

The layers of conductive structures may include a plurality of layers 238a-238e that are vertically arranged and alternate with a plurality of layers 240a-240d in the z-direction (e.g., vertically alternate). The layers 238a-238e each include a layer of metallization structures 242, and the layers 240a-240d each include a layer of interconnect structures 244.

The layers 238a-238e of metallization structures 242 may be referred to as M-layers. For example, a layer 238a of metallization structures 242 (referred to as a metal-0 (M0) layer) may be located at the bottom of the interconnect layer 224 and may be coupled to the device layer 222. In particular, the metallization structures 242 in the M0 layer may be coupled to the contacts 232 (e.g., a contact layer referred to as “CO”-layer) of the integrated circuit devices 228 in the device layer 222. A layer 238b of metallization structures 242 (referred to as a metal-1 (M1) layer) may be located above the layer 238a of metallization structures 242 in the interconnect layer 224, a layer 238c of metallization structures 242 (referred to as a metal-2 (M2) layer) may be located above a layer 238b of metallization structures 242, and so on.

A layer 240a of interconnect structures 244 (referred to as a via-0 (V0) layer) may be included between the M0 layer and the M1 layer to interconnect the M0 layer and the M1 layer, a layer 240b of interconnect structures 244 (referred to as a via-1 (V1) layer) may be included between the M1 layer and the M2 layer to interconnect the M1 layer and the M2 layer, and so on.

The metallization structures 242 may include a combination of trenches, metallization layers, conductive traces, and/or other types of conductive structures. The interconnect structures 244 may include a combination of vias, interconnects, and/or other types of conductive structures. The metallization structures 242 and the interconnect structures 244 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 224 and the metallization structures 242, and/or between the dielectric layers of the interconnect layer 224 and the interconnect structures 244. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 242, a topmost layer of interconnect structures 244) may be coupled to connection structures at the top of the semiconductor device 200. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 242, a topmost layer of interconnect structures 244) may be coupled to bonding structures, such as bonding pads and/or bonding vias.

As explained in more detail herein, the lithographic patterns for forming the integrated circuit devices 228, contacts 232, metallization structures 242, and interconnect structures 244 in the first exposure region 206 are formed using a first reticle, and the lithographic patterns for forming the integrated circuit devices 228, contacts 232, metallization structures 242, and interconnect structures 244 in the second exposure region 208 are formed using a second reticle.

As indicated above, FIGS. 2A and 2B are provided as an example. Other examples may differ from what is described with regard to FIGS. 2A and 2B.

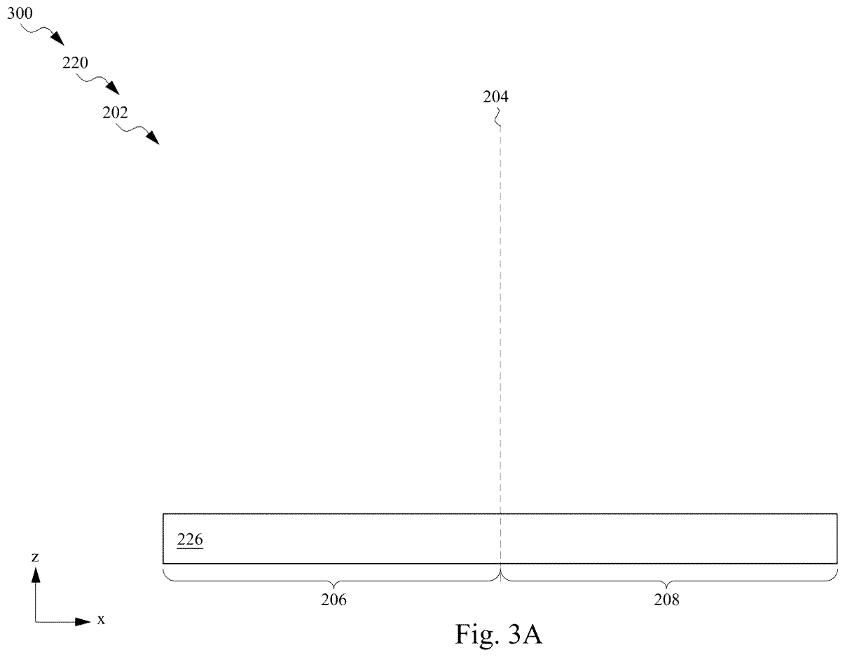

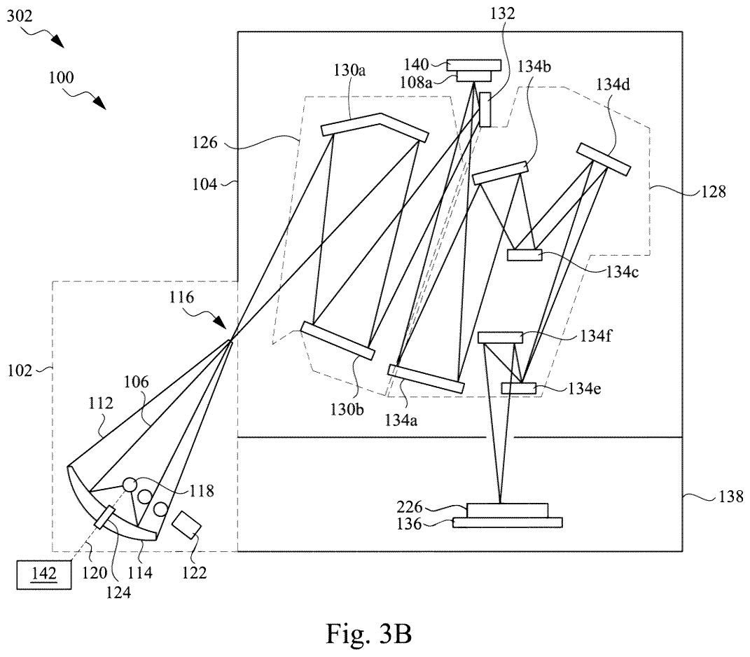

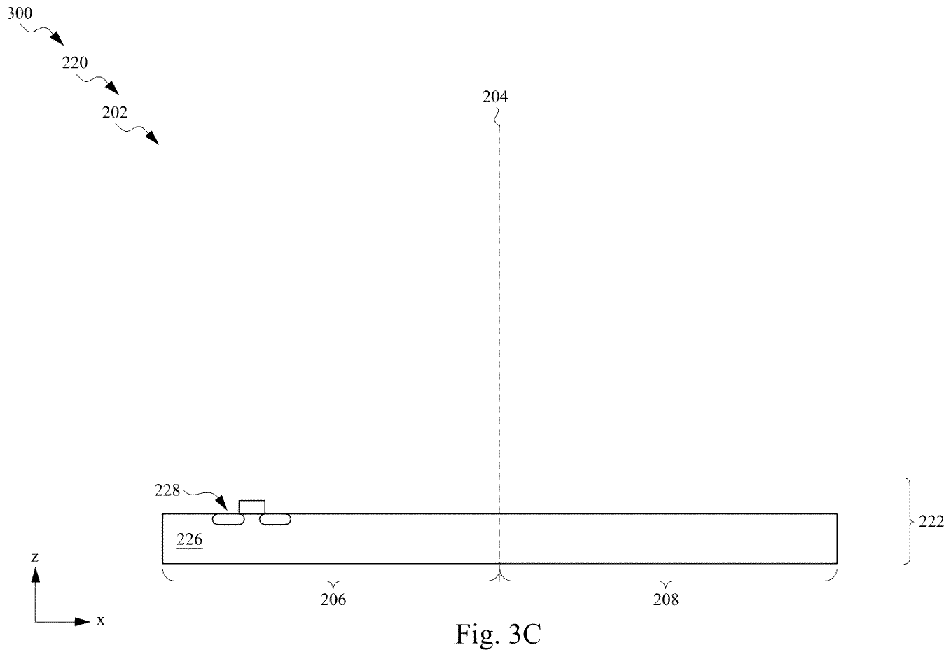

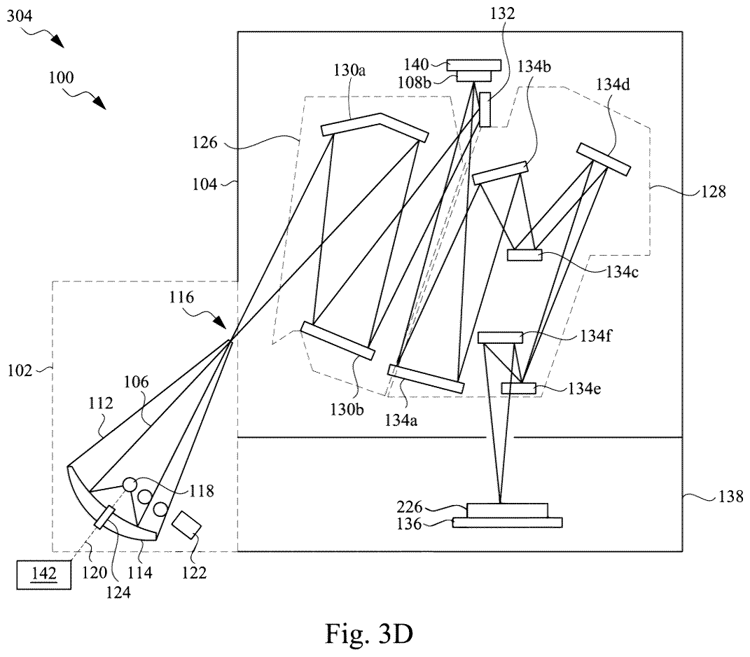

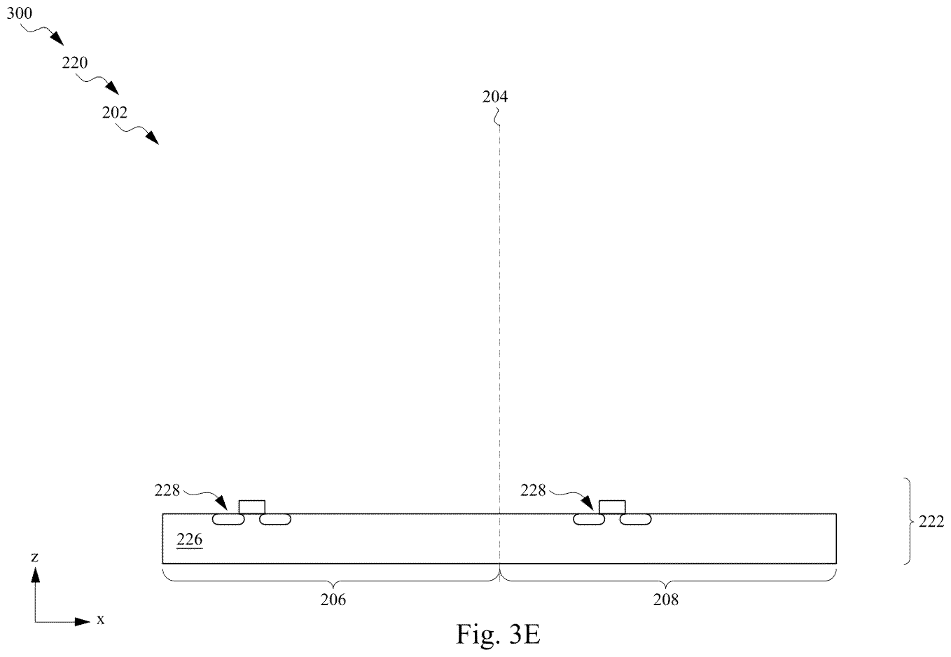

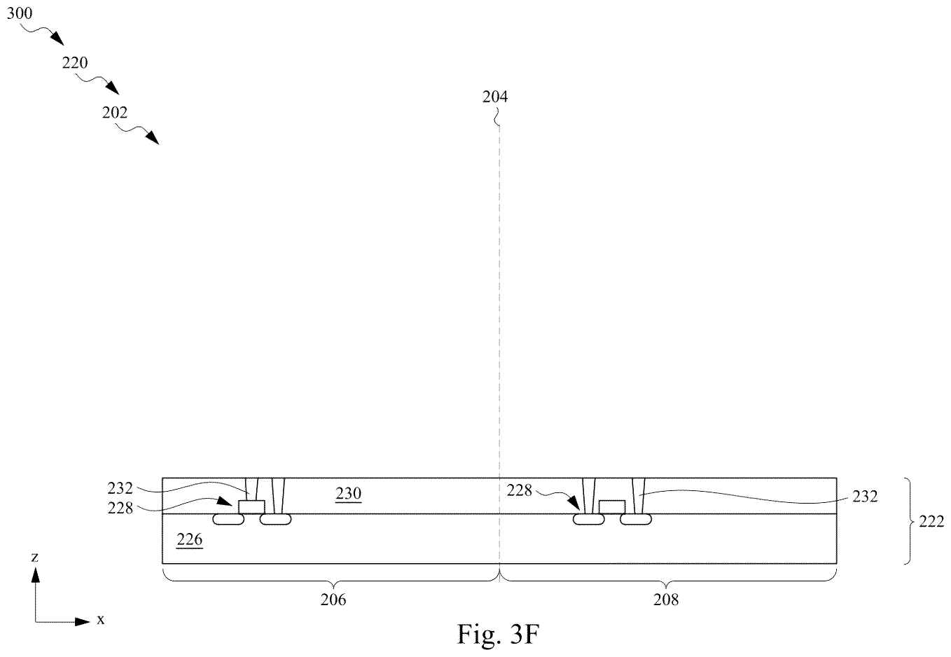

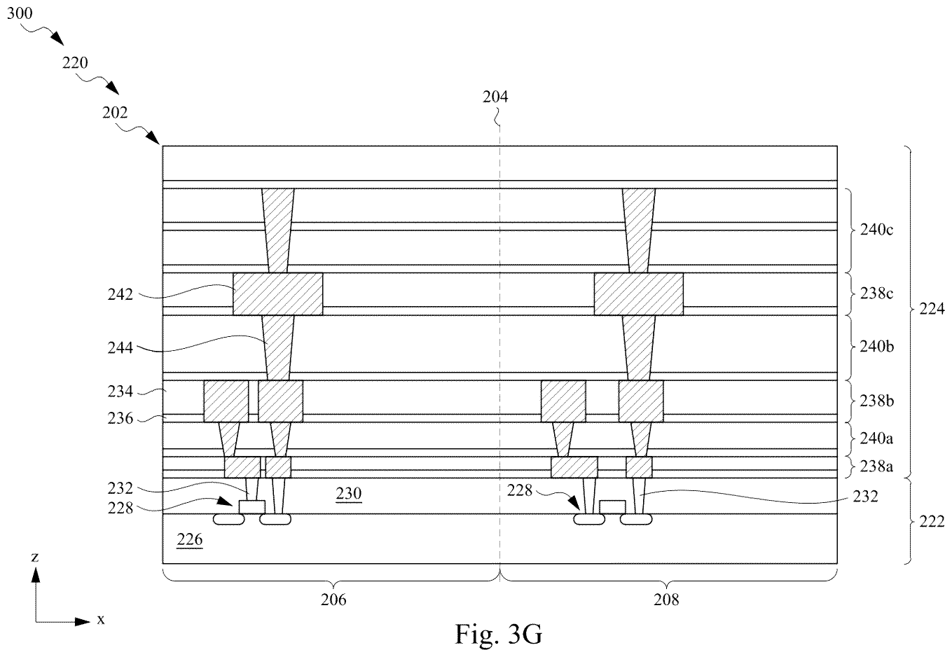

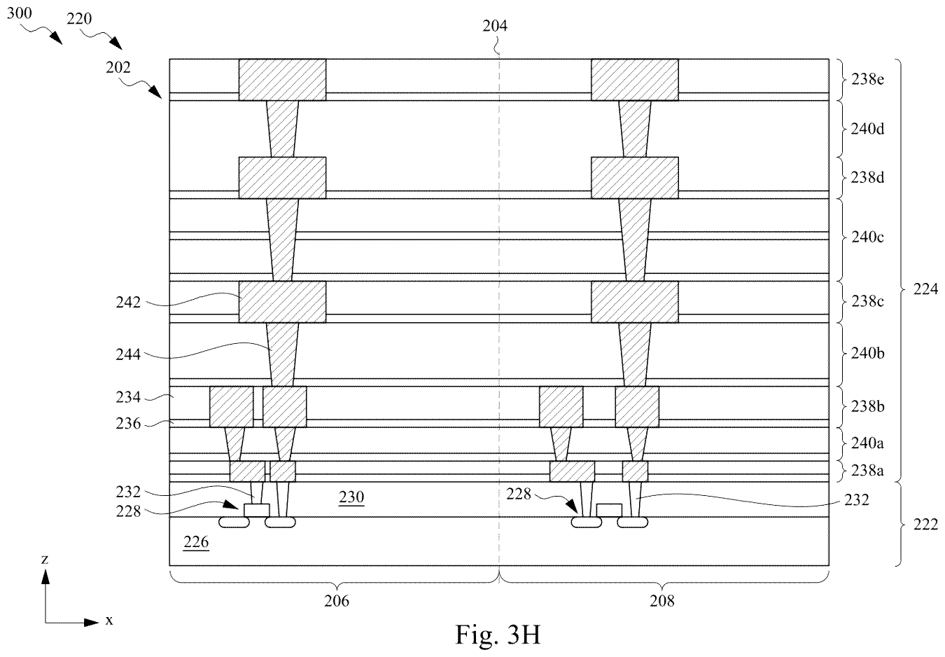

FIGS. 3A-3H are diagrams of an example implementation 300 of forming the semiconductor chip 202 described herein. In some implementations, one or more of the semiconductor processing operations described in connection with FIGS. 3A-3H may be performed using one or more semiconductor processing tools, such as a deposition tool, an exposure tool (e.g., exposure tool 104), a developer tool, an etch tool, a planarization tool, an ion implantation tool, a wafer/die transport tool, and/or another type of semiconductor processing tool.

Turning to FIG. 3A, the substrate 226 is provided. The substrate 226 may be provided in the form of a semiconductor wafer such as a silicon (Si) wafer, an SOI wafer, and/or another type of semiconductor work piece. The semiconductor chip 202 may be formed on the semiconductor wafer with other semiconductor chips. The substrate 226 includes the first exposure region 206 and the second exposure region 208.

FIG. 3B depicts an example implementation 302 of the lithography system 100 including a first reflective reticle 108a. The exposure tool 104 may focus the radiation 106 onto the first reflective reticle 108a (or a first photomask) such that a pattern is transferred from the first reflective reticle 108a onto the first exposure region 206 of the semiconductor substrate 226 using the radiation 106. The reflective mirrors 130a and 130b of the illuminator 126 may be configured to focus and/or direct the radiation 106 onto the first reflective reticle 108a so as to illuminate the pattern on the first reflective reticle 108a. The mirror 132 may direct radiation 106 from the illuminator 126 onto the first reflective reticle 108a.

The plurality of mirrors 134a-134f of the projection optics box 128 may be configured to project the radiation 106 onto the semiconductor substrate 226 after the radiation 106 is modified based on the pattern of the first reflective reticle 108a. The mirrors 134a-134f may be configured to focus or reduce the radiation 106 into the first exposure region 206 on the semiconductor substrate 226.

The mirror 130a reflects the radiation 106 onto the mirror 130b, which reflects the radiation 106 onto the mirror 132 toward the first reflective reticle 108a. The radiation 106 is modified by the pattern in the first reflective reticle 108a. In other words, the radiation 106 reflects off of the first reflective reticle 108a based on the pattern of the first reflective reticle 108a. The first reflective reticle 108a directs the radiation 106 toward the mirror 134a in the projection optics box 128, which reflects the radiation 106 onto the mirror 134b. The radiation 106 continues to be reflected and reduced in the projection optics box 128 by the mirrors 134c-134f. The mirror 134f reflects the radiation 106 into the first exposure region 206 on the semiconductor substrate 226 such that the pattern of the first reflective reticle 108a is transferred to the first exposure region 206 on the semiconductor substrate 226.

As shown in FIG. 3C, in connection with an exposure operation using the first reflective reticle 108a in the example implementation 302, the integrated circuit devices 228 may be formed in the first exposure region 206 in and/or on the substrate 226 in the device layer 222. The exposure tool 104 may be used to expose photoresist layers to form patterns in the photoresist layers in the first exposure region 206. One or more semiconductor processing tools in addition to the exposure tool 104 may be used to form one or more portions of the integrated circuit devices 228 in the first exposure region 206. For example, an ion implantation tool may be used to dope one or more regions in the substrate 226 with one or more types of dopants to form well regions, implant regions, and/or other types of doped regions in the substrate 226 for the integrated circuit devices 228. As another example, a deposition tool may be used to perform various deposition operations to deposit layers and/or structures of the integrated circuit devices 228, and/or to deposit photoresist layers for etching the substrate 226 and/or portions of the deposited layers. As another example, a developer tool may develop the patterns in the photoresist layers. As another example, an etch tool may be used to etch the substrate 226 and/or portions of the deposited layers to form the integrated circuit devices 228. As another example, a planarization tool may be used to planarize portions of the integrated circuit devices 228. As another example, a plating tool may be used to deposit metal structures and/or layers of the integrated circuit devices 228.

FIG. 3D depicts an example implementation 304 of the lithography system 100 including a second reflective reticle 108b. The exposure tool 104 may focus the radiation 106 onto the second reflective reticle 108b (or a second photomask) such that a pattern is transferred from the second reflective reticle 108b onto the second exposure region 208 of the semiconductor substrate 226 using the radiation 106. The reflective mirrors 130a and 130b of the illuminator 126 may be configured to focus and/or direct the radiation 106 onto the second reflective reticle 108b so as to illuminate the pattern on the second reflective reticle 108b. The mirror 132 may direct radiation 106 from the illuminator 126 onto the second reflective reticle 108b.

The plurality of mirrors 134a-134f of the projection optics box 128 may be configured to project the radiation 106 onto the semiconductor substrate 226 after the radiation 106 is modified based on the pattern of the second reflective reticle 108b. The mirrors 134a-134f may be configured to focus or reduce the radiation 106 into the second exposure region 208 on the semiconductor substrate 226.

The mirror 130a reflects the radiation 106 onto the mirror 130b, which reflects the radiation 106 onto the mirror 132 toward the second reflective reticle 108b. The radiation 106 is modified by the pattern in the second reflective reticle 108b. In other words, the radiation 106 reflects off of the second reflective reticle 108b based on the pattern of the second reflective reticle 108b. The second reflective reticle 108b directs the radiation 106 toward the mirror 134a in the projection optics box 128, which reflects the radiation 106 onto the mirror 134b. The radiation 106 continues to be reflected and reduced in the projection optics box 128 by the mirrors 134c-134f. The mirror 134f reflects the radiation 106 into the second exposure region 208 on the semiconductor substrate 226 such that the pattern of the second reflective reticle 108b is transferred to the second exposure region 208 on the semiconductor substrate 226.

As shown in FIG. 3E, in connection with an exposure operation using the second reflective reticle 108b in the example implementation 304, the integrated circuit devices 228 may be formed in the second exposure region 208 in and/or on the substrate 226 in the device layer 222. The exposure operation using the second reflective reticle 108b in the example implementation 304, and the formation of the integrated circuit devices 228 in the second exposure region 208, may be performed in sequence after the exposure operation using the first reflective reticle 108a in the example implementation 302, and after the formation of the integrated circuit devices 228 in the first exposure region 206.

In more detail, after using the first reflective reticle 108a to form patterns in the photoresist layers in the first exposure region 206 for the formation of the integrated circuit devices 228 in the first exposure region 206, the exposure tool 104 may use the second reflective reticle 108b to form patterns in the photoresist layers in the second exposure region 208 for the formation of the integrated circuit devices 228 in the second exposure region 208. Similar to the formation of the integrated circuit devices 228 in the first exposure region 206, one or more semiconductor processing tools in addition to the exposure tool 104 may be used to form one or more portions of the integrated circuit devices 228 in the second exposure region 208.

As shown in FIG. 3F, a deposition tool is used to deposit the dielectric layer 230 over and/or on the substrate 226 and over and/or on the integrated circuit devices 228 in the first exposure region 206 and in the second exposure region 208. A deposition tool may be used to deposit the dielectric layer 230 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 230 after the dielectric layer 230 is deposited.

As further shown in FIG. 3F, the contacts 232 of the integrated circuit devices 228 in the first exposure region 206 and in the second exposure region 208 may be formed through the dielectric layer 230. The contacts 232 may be formed in recesses in the dielectric layer 230. In some implementations, a pattern in a photoresist layer is used to etch the dielectric layer 230 to form the recesses. In these implementations, a deposition tool may be used to form the photoresist layer on the dielectric layer 230. The exposure tool 104 may be used to expose the photoresist layer to the radiation 106 to pattern the photoresist layer. The patterns used to etch the portion of the dielectric layer 230 in the first exposure region 206 may be formed using the first reflective reticle 108a in a first exposure process. The patterns used to etch the portion of the dielectric layer 230 in the second exposure region 208 may be formed using the second reflective reticle 108b in a second exposure process after the first exposure process. As explained in more detail in connection with FIGS. 3G and 3H, exposures using the first and second reflective reticles 108a and 108b may be alternately performed for different layers on the semiconductor chip 202 until all layers of the semiconductor chip 202 have been formed.

A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

The contacts 232 may be formed in the recesses. In some implementations, a contact 232 (e.g., a gate contact) is formed on a gate structure of an integrated circuit device 228. In some implementations, a contact 232 (e.g., a source/drain contact) is formed on a source/drain region of an integrated circuit device 228. A deposition tool may be used to deposit the material of the contacts 232 in the recesses using a CVD technique, a PVD technique, an ALD technique, an electroplating technique, and/or another suitable deposition technique. The material of the contacts 232 may be deposited in one or more deposition operations. In some implementations, a seed layer is first deposited, and the material of the contacts 232 is deposited on the seed layer. In some implementations, a planarization tool is used to perform a planarization operation (e.g., a CMP operation) to planarize the contacts 232 after the contacts 232 are deposited such that the tops of the contacts 232 are approximately co-planar with the top of the dielectric layer 230.

As shown in FIG. 3G, first part of the interconnect layer 224 of the semiconductor chip 202 is formed above the dielectric layer 230. One or more deposition tools are used to deposit alternating layers of ILD layers 234 and ESLs 236 in the first portion of the interconnect layer 224. In this way, the ILD layers 234 and ESLs 236 may be arranged in the z-direction on the semiconductor chip 202. One or more deposition tools may be used to deposit each of the ILD layers 234 and each of the ESLs 236 using a PVD technique, an ALD technique, a CVD technique, an oxidation technique, and/or another suitable deposition technique. In some implementations, a planarization tool may be used to planarize the ILD layers 234 and/or the ESLs 236 after the ILD layers 234 and/or the ESLs 236 are deposited.

As further shown in FIG. 3G, a deposition tool, an exposure tool (e.g., exposure tool 104), a developer tool, an etch tool, a planarization tool, a plating tool, and/or another semiconductor processing tool may be used to perform various operations to form the metallization structures 242 and to form the interconnect structures 244 in the interconnect layer 224 in the first exposure region 206, and in the second exposure region 208.

The metallization structures 242 and the interconnect structures 244 may be formed in recesses in the ILD layers 234 and in the ESLs 236. In some implementations, a pattern in a photoresist layer is used to etch the ILD layers 234 and the ESLs 236 to form the recesses. In these implementations, a deposition tool may be used to form the photoresist layer on one or more of the ILD layers 234 and/or one or more of the ESLs 236. The exposure tool 104 may be used to expose the photoresist layer to the radiation 106 to pattern the photoresist layer. The patterns used to etch the portions of the ILD layers 234 and the ESLs 236 in the first exposure region 206 may be formed using the first reflective reticle 108a in a first exposure process. The patterns used to etch the portions of the ILD layers 234 and the ESLs 236 in the second exposure region 208 may be formed using the second reflective reticle 108b in a second exposure process after the first exposure process. Exposures using the first and second reflective reticles 108a and 108b may be alternately performed for different parts of the interconnect layer 224 until the metallization structures 242 in the layers 238a-238e, and the interconnect structures 244 in the layers 240a-240d, have been formed.

In some implementations, the interconnect layer 224 may be formed in a plurality of stages where the exposures using the first and second reflective reticles 108a and 108b are alternately performed. For example, an ILD layer 234 and an ESL 236 may be formed (e.g., using one or more deposition tools and/or one or more planarization tools), recesses may be formed in and/or through the ILD layer 234 and the ESL 236 (e.g., using an exposure tool 104 with first and second reflective reticles 108a and 108b for first and second exposure regions 206 and 208, a developer tool, and/or an etch tool), and the layer 238a (e.g., the M0 layer) of metallization structures 242 may be formed in the ILD layer 234 and the ESL 236 (e.g., using one or more deposition tools and/or one or more planarization tools). Another ILD layer 234 and another ESL 236 may be formed, and the layer 240a (e.g., the V0 layer) of interconnect structures 244 may be formed in the ILD layer 234 and the ESL 236. The layers 238b, 238c, 240b, and 240c may be formed in a similar manner.

One or more deposition tools may be used to deposit the metallization structures 242, and the interconnect structures 244 using a PVD technique, an ALD technique, a CVD technique, an electroplating technique (e.g., an electro-chemical plating technique), and/or another suitable deposition technique. In some implementations, a planarization tool may be used to planarize the metallization structures 242 and the interconnect structures 244, after the metallization structures 242 and the interconnect structures 244 are deposited.

As shown in FIG. 3H, a second part of the interconnect layer 224 is formed in the first exposure region 206 and in the second exposure region 208. The second part of the interconnect layer 224 may be formed in a similar manner as the first part of the interconnect layer 224, as described in connection with FIG. 3G.

The exposure operations described in connection with FIGS. 3A-3H are examples, and the lithography system 100 may operate according to other EUV techniques and radiation paths that include a greater quantity of mirrors, a lesser quantity of mirrors, and/or a different configuration of mirrors.

As indicated above, FIGS. 3A-3H are provided as an example. Other examples may differ from what is described with regard to FIGS. 3A-3H.

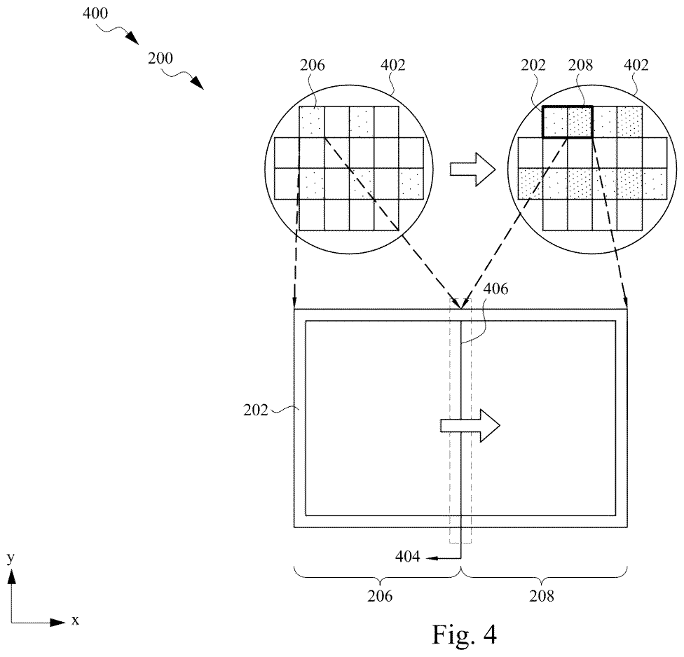

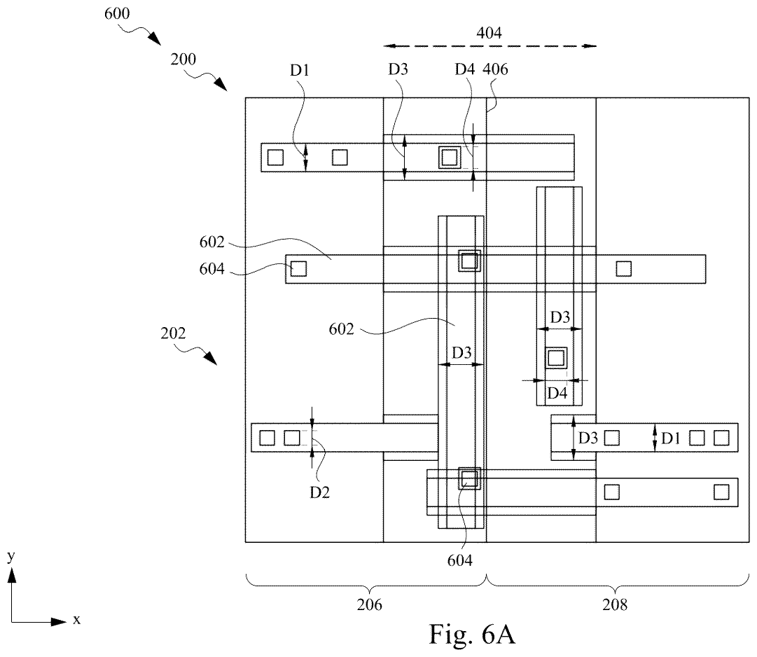

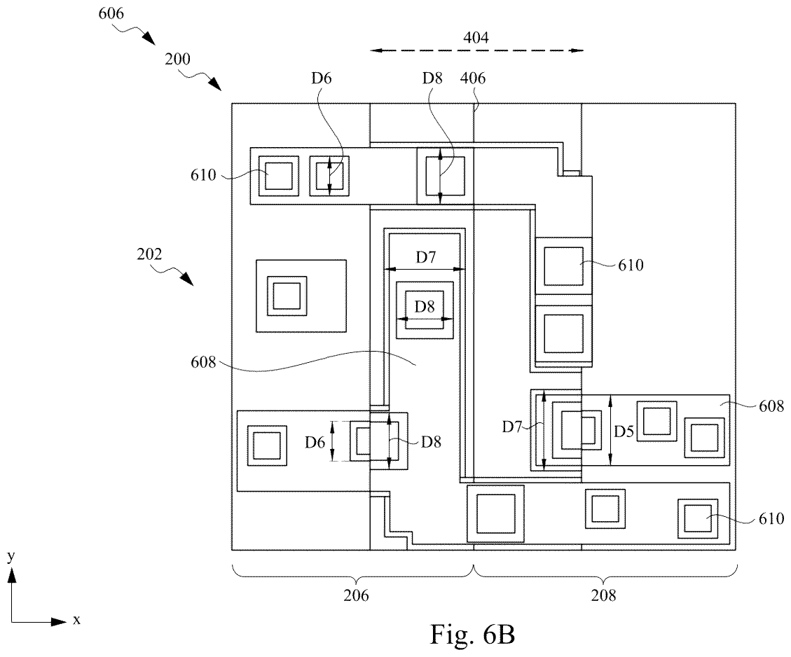

FIG. 4 is a diagram of an example implementation 400 of the semiconductor device 200. As shown in FIG. 4, a plurality of semiconductor chips 202, each including a first exposure region 206 and a second exposure region 208, are manufactured on a semiconductor wafer 402, such as a silicon (Si) wafer, an SOI wafer, and/or another type of semiconductor work piece. A correction region 404 is located at and/or adjacent to an interface 406 between the first exposure region 206 and the second exposure region 208. In some implementations, the correction region 404 includes an optical proximity correction (OPC) region, a logic operation (LOP) region, and/or a region in which components are not formed. The correction region 404 may compensate for lithography errors that may be produced at reticle edges where elements formed on a wafer may not match with the actual design of the elements. The errors may include, for example, size differences, edge location differences, and/or contour differences, among other differences from the actual design, that may result in performance issues such as open circuits and/or shorts. In some implementations, the errors may be corrected in the correction region 404 by modifying a pattern for one or more elements at the reticle edges by adding additional shapes and/or changing the location of edges of an element to be patterned in one or more directions. For example, the edges or boundaries of an element (e.g., trench) may be moved in the x-direction or y-direction to increase the size of a portion of an element inside the correction region 404 relative to the size of a portion of the element outside of the correction region 404. As described in more detail in connection with FIGS. 6A and 6B, the modifications to the elements for the correction region 404 may be made to the reticle patterns, and may be translated to differences (e.g., size differences) between portions of actual structures formed inside the correction region 404 and outside of the correction region 404. A logic operation (LOP) may be performed to generate the compensatory reticle patterns for the correction region 404. In some implementations, the correction region 404 may be used to define a critical device region, such that components are not formed in the correction region 404, with the critical device region (e.g., a region where components, circuitry, conductive structures, etc. are formed) being outside of the correction region 404.

As shown in FIG. 4, the correction region 404 corresponds to a portion of the semiconductor chip 202 where edges of the first and second exposure regions 206 and 208 interface with each other. In other words, the correction region 404 is at a portion of the semiconductor chip 202 where patterning by a first reticle (e.g., first reflective reticle 108a) ends, and patterning by a second reticle (e.g., second reflective reticle 108b) begins. In more detail, the correction region 404 is at and/or adjacent to an interface 406 between the first and second exposure regions 206 and 208, includes a part (e.g., an end portion) of the first exposure region 206, and includes a part (e.g., an end portion) of the second exposure region 208.

As shown by the arrows in FIG. 4, a first exposure operation using a first reticle (e.g., first reflective reticle 108a) to form structures (e.g., integrated circuit devices 228 and/or trenches/recesses for metallization structures 242 and/or interconnect structures 244) in the first exposure region 206 is followed by a second exposure operation using a second reticle (e.g., second reflective reticle 108b) to form the structures in the second exposure region 208. Exposure operations using first and second reticles may be alternately performed for layers of the semiconductor chip 202 until chip fabrication is completed. The use of multiple reticles (e.g., in this case, two reticles) in multiple exposure operations (e.g., in this case, two exposure operations) enables the formation of a large area (e.g., greater than 26×33 mm² (858 mm²)) semiconductor chip 202. The large area semiconductor chip 202 may incorporate various circuit functions that may be needed for HPC functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

As indicated above, FIG. 4 is provided as an example. Other examples may differ from what is described with regard to FIG. 4.

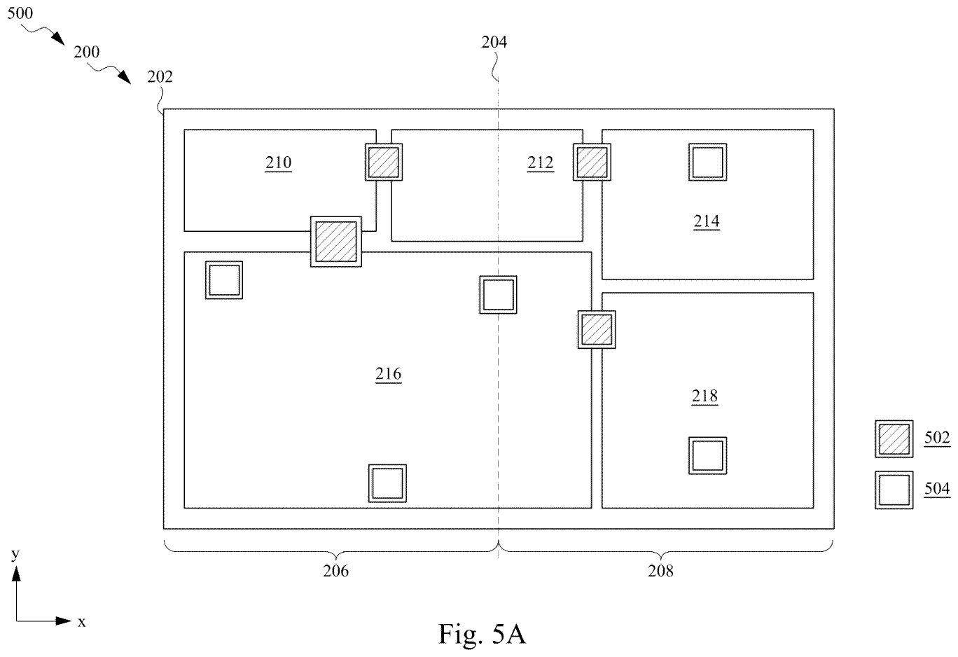

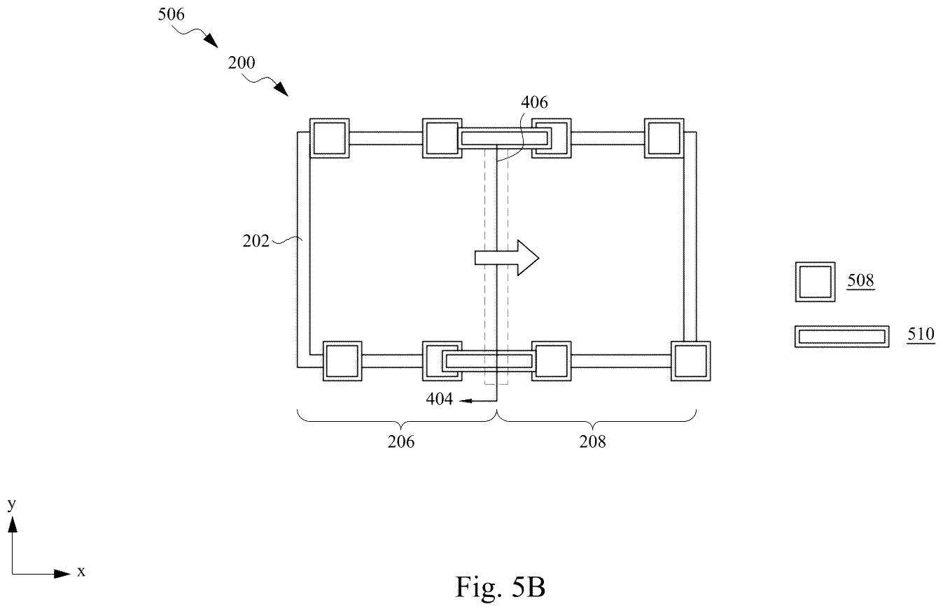

FIGS. 5A and 5B are diagrams of example implementations 500 and 506 of a semiconductor device 200. The example implementation 500 is similar to the example implementation shown in FIG. 2A. In addition to elements 202-218, the example implementation 500 includes a plurality of in-chip alignment marks 502 and 504. Semiconductor devices are manufactured using patterning techniques to transfer layer designs on a photomask or reticle to a semiconductor substrate and/or chip. The semiconductor devices are built up layer by layer using a sequence of deposition, patterning, and etching techniques, among other examples. Accordingly, the precise alignment of layers in a semiconductor device (referred to as overlay or OVL) is an important parameter of achieving high yield and low rework rate in semiconductor manufacturing.

A substrate and/or chip may include one or more alignment marks to facilitate precise and repeatable alignment of the substrate and/or chip across a plurality of semiconductor processing operations. An alignment mark includes a region of the substrate and/or chip that includes an alignment pattern that can be scanned and tracked to fine-tune the orientation of the substrate and/or chip. A laser illumination system of a lithography tool, for example, may scan the pattern of the alignment mark to generate alignment data that may be used to determine whether the alignment of the substrate and/or chip is a pass or a fail. Moreover, the alignment data may be used to generate OVL compensation values for fine-tuning the alignment for subsequent semiconductor processes.

The in-chip alignment marks 502 are disposed between functional areas 210-218 (e.g., circuit blocks) such that the in-chip alignment marks 502 may overlap multiple (e.g., two or more) functional areas 210-218. The in-chip alignment marks 504 are disposed within a functional area 210-218 (e.g., circuit blocks) without overlapping another functional area 210-218. In some cases, as shown in FIG. 5A, one or more in-chip alignment marks 504 may be disposed such that a first part of the in-chip alignment mark is disposed in the first exposure region 206, a second part of the in-chip alignment mark is disposed in the second exposure region 208, and a third part of the in-chip alignment mark is disposed between the first exposure region 206 and the second exposure region 208, that is, at the interface of the first exposure region 206 and the second exposure region 208.

As shown in FIG. 5B, the example implementation 506 of the semiconductor device 200 is similar to the example implementation 400 of the semiconductor device 200. For example, in the example implementation 506, like the example implementation 400, the semiconductor chip 202 includes the first and second exposure regions 206 and 208, and the correction region 404 at and/or adjacent to the interface 406 between the first and second exposure regions 206 and 208. In addition, as shown in the example implementation 506, the semiconductor chip 202 includes frame alignment marks 508 at corners of the first exposure region 206 and at corners of the second exposure region 208. Similar to the in-chip alignment marks 502 and 504, the frame alignment marks 508 facilitate precise and repeatable alignment of the substrate and/or chip across a plurality of semiconductor processing operations to result in a high yield and a low rework rate in semiconductor manufacturing. The frame alignment marks 508 are disposed along external edges of the substrate and/or semiconductor chip 202 and include a scannable and/or trackable alignment pattern to fine-tune substrate and/or chip orientation.

In the example implementation 506, the semiconductor chip 202 also includes process control monitoring (PCM) structures 510 at and/or adjacent to the interface 406 between the first and second exposure regions 206 and 208, and along edges of the semiconductor chip 202. For example, the PCM structures 510 may extend from and between the first and second exposure regions 206 and 208, and may overlap one or more frame alignment marks 508 in the first and second exposure regions 206 and 208. The PCM structures 510 overlap parts of the correction region 404, and may be disposed on opposite edges of the semiconductor chip 202. In some implementations, the PCM structures 510 provide device and/or metal continuity between the first and second exposure regions 206 and 208. The PCM structures 510 may also be used for resistance monitoring and/or for monitoring other operational characteristics and/or features of the semiconductor chip 202 in order to improve device performance.

As indicated above, FIGS. 5A and 5B are provided as an example. Other examples may differ from what is described with regard to FIGS. 5A and 5B.

FIGS. 6A and 6B are diagrams of example implementations of a semiconductor device 200. In some implementations, the example implementation 600 may correspond to the metallization structures 242 and the interconnect structures 244 of the first part of the interconnect layer 224 (e.g., layers 238a-238c, and layers 240a-240c) as shown in FIG. 3G, and the example implementation 606 may correspond to the metallization structures 242 and the interconnect structures 244 of the second part of interconnect layer 224 (e.g., layers 238d-238e, and layer 240d) as shown in FIG. 3H. As shown in FIG. 6A, the example implementation 600 is similar to the example implementation 400 of the semiconductor device 200 in that the semiconductor chip 202 includes the first and second exposure regions 206 and 208, and the correction region 404 at and/or adjacent to the interface 406 between the first and second exposure regions 206 and 208. In addition, as shown in the example implementation 600, the semiconductor chip 202 further includes conductive structures including metallization structures 602 and interconnect structures 604. Some of the conductive structures include portions inside the correction region 404 and outside of the correction region 404. For example, portions of a metallization structure 602 and/or of an interconnect structure 604 may be formed in the first exposure region 206, in the correction region 404, and in the second exposure region 208. Another metallization structure 602 and/or interconnect structure 604 may include portions in the first exposure region 206 and in the correction region 404. In another example, a metallization structure 602 and/or interconnect structure 604 may include portions in the second exposure region 208 and in the correction region 404. In some implementations, a metallization structure 602 and/or interconnect structure 604 is formed only in the correction region 404, only in the first exposure region 206, or only in the second exposure region 208.

As noted herein, in some implementations, lithography errors that may be produced at reticle edges may be corrected in the correction region 404 by moving the edges or boundaries of an element (e.g., trench) in the x-direction or y-direction to increase the size of a portion of an element inside the correction region 404 relative to the size of a portion of the element outside of the correction region 404. In more detail, referring to FIG. 6A, the modifications to the elements for the correction region 404 may be made to the reticle patterns, and may be translated to differences (e.g., size differences) between portions of actual structures formed inside the correction region 404 and outside of the correction region 404. For example, metallization structures 602 and interconnect structures 604 outside of the correction region 404 have dimensions D1 and D2, respectively, in the x-or y-directions (e.g., x-axis or y-axis). In contrast, metallization structures 602 and interconnect structures 604 inside the correction region 404 have dimensions D3 and D4, respectively, in the x-or y-directions. As shown in FIG. 6A, the dimension D3 of the metallization structures 602 or of portions of the metallization structures 602 inside the correction region 404 is larger than the dimension D1 of the metallization structures 602 or of portions of the metallization structures 602 outside of the correction region 404. Similarly, the dimension D4 of the interconnect structures 604 inside the correction region 404 is larger than the dimension D2 of the interconnect structures 604 outside of the correction region 404.

As shown in FIG. 6B, the example implementation 606 is similar to the example implementation 400 of the semiconductor device 200 in that the semiconductor chip 202 includes the first and second exposure regions 206 and 208, and the correction region 404 at and/or adjacent to the interface 406 between the first and second exposure regions 206 and 208. In addition, as shown in the example implementation 606, the semiconductor chip 202 further includes conductive structures including metallization structures 608 and interconnect structures 610. Some of the conductive structures include portions inside the correction region 404 and outside of the correction region 404. For example, portions of a metallization structure 608 and/or of an interconnect structure 610 may be formed in the first exposure region 206, in the correction region 404, and in the second exposure region 208. Another metallization structure 608 and/or interconnect structure 610 may include portions in the first exposure region 206 and in the correction region 404. In another example, a metallization structure 608 and/or interconnect structure 610 may include portions in the second exposure region 208 and in the correction region 404. In some implementations, a metallization structure 608 and/or interconnect structure 610 is formed only in the correction region 404, only in the first exposure region 206, or only in the second exposure region 208.

As noted herein, in some implementations, lithography errors that may be produced at reticle edges may be corrected in the correction region 404 by moving the edges or boundaries of an element (e.g., trench) in the x-direction or y-direction to increase the size of a portion of an element inside the correction region 404 relative to the size of a portion of the element outside of the correction region 404. In more detail, referring to FIG. 6B, the modifications to the elements for the correction region 404 may be made to the reticle patterns, and may be translated to differences (e.g., size differences) between portions of actual structures formed inside the correction region 404 and outside of the correction region 404. For example, metallization structures 608 and interconnect structures 610 outside of the correction region 404 have dimensions D5 and D6, respectively, in the x- or y-directions (e.g., x-axis or y-axis). In contrast, metallization structures 608 and interconnect structures 610 inside the correction region 404 have dimensions D7 and D8, respectively, in the x- or y-directions. As shown in FIG. 6B, the dimension D7 of the metallization structures 608 or of portions of the metallization structures 608 inside the correction region 404 is larger than the dimension D5 of the metallization structures 608 or of portions of the metallization structures 608 outside of the correction region 404. Similarly, the dimension D8 of the interconnect structures 610 or of portions of the interconnect structures 610 inside the correction region 404 is larger than the dimension D6 of the interconnect structures 610 or of portions of the interconnect structures 610 outside of the correction region 404. For the metallization structures 602 and 608, and for the interconnect structures 604 and 610, portions disposed inside the correction region 404 and outside of the correction region 404 may be contiguous with each other.

As indicated above, FIGS. 6A and 6B are provided as an example. Other examples may differ from what is described with regard to FIGS. 6A and 6B.

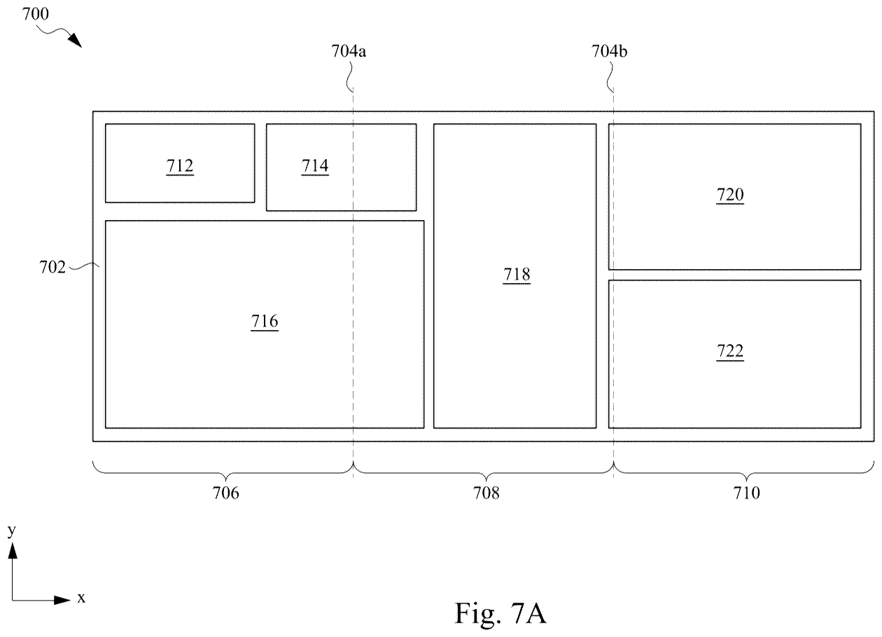

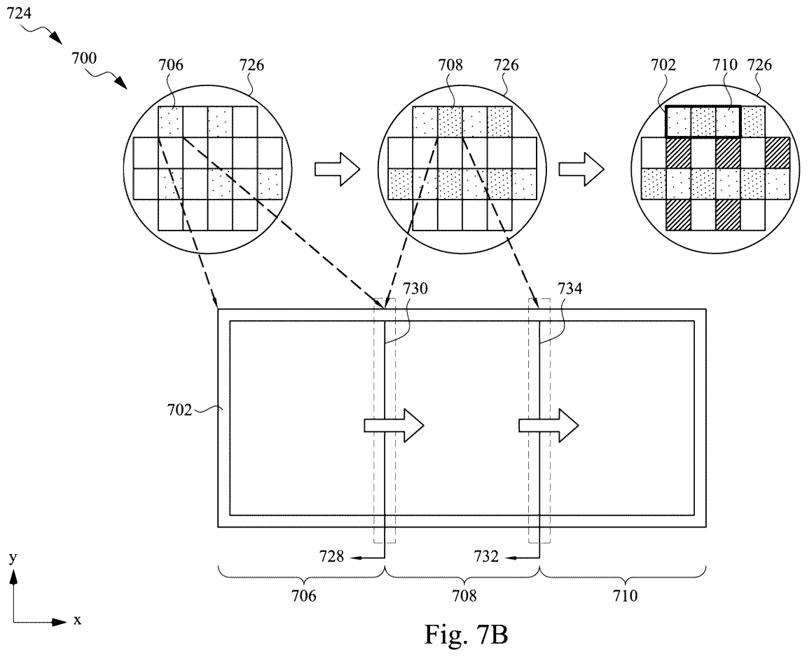

FIGS. 7A and 7B are diagrams of an example semiconductor device 700. As shown in FIG. 7A, a semiconductor device 700 includes a semiconductor chip 702. The semiconductor chip 702 may include one or more semiconductor dies with circuits configured to perform different functions. For example, the semiconductor chip 702 may include multiple dies to perform multiple HPC functions. The semiconductor chip 702 may include one or more SoC dies. An SoC die may include, for example, a logic die, a CPU die, a GPU die, a DSP die, an ASIC die, and/or another type of SoC die. Additionally and/or alternatively, the semiconductor chip 702 may include one or more of a memory die, an I/O die, a pixel sensor die, and/or another type of semiconductor die. A memory die may include an SRAM die, a DRAM die, a NAND die, an HBM die, and/or another type of memory die.

As indicated by the dotted lines 704a and 704b, the semiconductor chip 702 is divided into a first exposure region 706, a second exposure region 708, and a third exposure region 710. The first, second, and third exposure regions 706, 708, and 710 are arranged next to each other along the x-direction. The first and second exposure regions 706 and 708 abut each other, and the second and third exposure regions 708 and 710 abut each other. The semiconductor chip 702 may include functional areas 712, 714, 716, 718, 720, and 722. In some implementations, the functional areas 712-722 each correspond to a die formed on the semiconductor chip 702, with each die including circuitry to perform and/or support HPC operations. For example, one or more of the functional areas 712-722 may include memory circuitry, analog circuitry, logic circuitry, radio frequency (RF) circuitry, CPU circuitry, GPU circuitry, DSP circuitry, power circuitry, ASIC circuitry, etc. In some implementations, respective functional areas 712-722 are different from each other. Alternatively, one or more the functional areas 712-722 may have the same or similar circuitry and/or correspond to the same or similar HPC functionality.

The first, second, and third exposure regions 706, 708, and 710 respectively correspond to first, second, and third portions of the semiconductor chip 702 that are patterned by different reticles of a lithography system during a manufacturing process. For example, the first exposure region 706 is patterned using a first reticle, the second exposure region 708 is patterned using a second reticle, and the third exposure region 710 is patterned using a third reticle. The entire functional area 712 is in the first exposure region 706, such that each of the elements that require patterning (e.g., lithography) in the functional area 712 is patterned using the first reticle. Similarly, the entire functional area 718 is in the second exposure region 708, such that each of the elements that require patterning in the functional area 718 is patterned using the second reticle. First parts of the functional areas 714 and 716 are in the first exposure region 706, and second parts of the functional areas 714 and 716 are in the second exposure region 708. The first part of the functional area 714 and the first part of the functional area 716 are patterned using the first reticle. The second part of the functional area 714 and the second part of the functional area 716 are patterned using the second reticle. First parts of the functional areas 720 and 722 are in the second exposure region 708, and second parts of the functional areas 720 and 722 are in the third exposure region 710. The first part of the functional area 720 and the first part of the functional area 722 are patterned using the second reticle. The second part of the functional area 720 and the second part of the functional area 722 are patterned using the third reticle.

FIG. 7B is a diagram of an example implementation 724 of the semiconductor device 700. As shown in FIG. 7B, a plurality of semiconductor chips 702, each including a first exposure region 706, a second exposure region 708, and a third exposure region 710 are manufactured on a semiconductor wafer 726, such as a silicon (Si) wafer, an SOI wafer, and/or another type of semiconductor work piece. A first correction region 728 is located at and/or adjacent to an interface 730 between the first exposure region 706 and the second exposure region 708, and a second correction region 732 is located at and/or adjacent to an interface 734 between the second exposure region 708 and the third exposure region 710. In some implementations, the first correction region 728 and the second correction region 732 include an OPC region, a LOP region, and/or a region in which components are not formed. The first and second correction regions 728 and 732 may compensate for lithography errors that may be produced at reticle edges where elements formed on a wafer may not match with the actual design of the elements. The errors may include, for example, size differences, edge location differences, and/or contour differences, among other differences from the actual design, that may result in performance issues such as open circuits and/or shorts. In some implementations, the errors may be corrected in the first and second correction regions 728 and 732 by modifying a pattern for one or more elements at the reticle edges by adding additional shapes and/or changing the location of edges of an element to be patterned in one or more directions. For example, the edges or boundaries of elements (e.g., trenches) may be moved in the x-direction or y-direction to increase the size of portions of the elements inside the first and second correction regions 728 and 732 relative to the size of portions of the elements outside of the first and second correction regions 728 and 732. Similar to what is described in connection with FIGS. 6A and 6B, the modifications to the elements for the first and second correction regions 728 and 732 may be made to the reticle patterns, and may be translated to differences (e.g., size differences) between portions of actual structures formed inside the first and second correction regions 728 and 732 and outside of the first and second correction regions 728 and 732. A logic operation (LOP) may be performed to generate the compensatory reticle patterns for the first and second correction regions 728 and 732. In some implementations, the first and/or second correction regions 728 and 732 may be used to define a critical device region, such that components are not formed in the first and/or second correction regions 728 and 732, with the critical device region (e.g., a region where components, circuitry, conductive structures, etc. are formed) being outside of the first and/or second correction regions 728 and 732.

As shown in FIG. 7B, the first correction region 728 corresponds to a portion of the semiconductor chip 702 where edges of the first and second exposure regions 706 and 708 interface with each other. In other words, the first correction region 728 is at a portion of the semiconductor chip 702 where patterning by a first reticle ends, and patterning by a second reticle begins. In more detail, the first correction region 728 is at and/or adjacent to an interface 730 between the first and second exposure regions 706 and 708, includes a part (e.g., an end portion) of the first exposure region 706, and includes part (e.g., an end portion) of the second exposure region 708. The second correction region 732 corresponds to a portion of the semiconductor chip 702 where edges of the second and third exposure regions 708 and 710 interface with each other. In other words, the second correction region 732 is at a portion of the semiconductor chip 702 where patterning by a second reticle ends, and patterning by a third reticle begins. In more detail, the second correction region 732 is at and/or adjacent to an interface 734 between the second and third exposure regions 708 and 710, includes a part (e.g., an end portion) of the second exposure region 708, and includes part (e.g., an end portion) of the third exposure region 710.

As shown by the arrows in FIG. 7B, a first exposure operation using a first reticle to form structures (e.g., integrated circuit devices and/or trenches/recesses for metallization structures and/or interconnect structures) in the first exposure region 706 is followed by a second exposure operation using a second reticle to form the structures in the second exposure region 708, which is followed by a third exposure operation using a third reticle to form the structures in the third exposure region 710. Exposure operations using first, second, and third reticles may be alternately performed for layers of the semiconductor chip 702 until chip fabrication is completed. The use of multiple reticles (e.g., in this case, three reticles) in multiple exposure operations (e.g., in this case, three exposure operations) enables the formation of a large area (e.g., greater than 26×33 mm² (858 mm²)) semiconductor chip 702. The large area semiconductor chip 702 may incorporate various circuit functions that may be needed for HPC functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

As indicated above, FIGS. 7A and 7B are provided as an example. Other examples may differ from what is described with regard to FIGS. 7A and 7B.

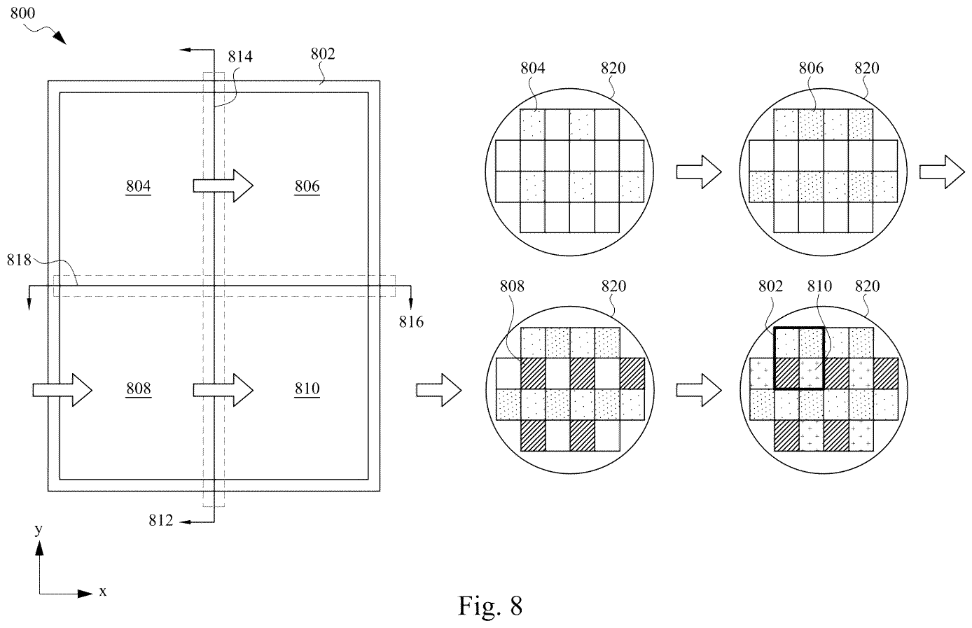

FIG. 8 is a diagram of an example implementation of a semiconductor device 800. As shown in FIG. 8, a plurality of semiconductor chips 802, each including a first exposure region 804, a second exposure region 806, a third exposure region 808, and a fourth exposure region 810 are manufactured on a semiconductor wafer 820, such as a silicon (Si) wafer, an SOI wafer, and/or another type of semiconductor work piece. The first and second exposure regions 804 and 806 are arranged next to each other along the x-direction. The third and fourth exposure regions 808 and 810 are arranged next to each other along the x-direction. The first and third exposure regions 804 and 808 are arranged next to each other along the y-direction. The second and fourth exposure regions 806 and 810 are arranged next to each other along the y-direction. The first and second exposure regions 804 and 806 abut each other, and the third and fourth exposure regions 808 and 810 abut each other along the x-direction. The first and third exposure regions 804 and 808 abut each other, and the second and fourth exposure regions 806 and 810 abut each other along the y-direction. The first, second, third, and fourth exposure regions 804, 806, 808, and 810 respectively correspond to first, second, third, and fourth portions of the semiconductor chip 802 that are patterned by different reticles of a lithography system during a manufacturing process. For example, the first exposure region 804 is patterned using a first reticle, the second exposure region 806 is patterned using a second reticle, the third exposure region 808 is patterned using a third reticle, and the fourth exposure region 810 is patterned using a fourth reticle.

A first correction region 812 is located at and/or adjacent to an interface 814 between the first exposure region 804 and the second exposure region 806, and between the third exposure region 808 and the fourth exposure region 810. A second correction region 816 is located at and/or adjacent to an interface 818 between the first exposure region 804 and the third exposure region 808, and between the second exposure region 806 and the fourth exposure region 810. The first correction region 812 intersects the second correction region 816. In some implementations, the first correction region 812 and the second correction region 816 include an OPC region, a LOP region, and/or a region in which components are not formed. The first and second correction regions 812 and 816 may compensate for lithography errors that may be produced at reticle edges where elements formed on a wafer may not match with the actual design of the elements. The errors may include, for example, size differences, edge location differences, and/or contour differences, among other differences from the actual design, that may result in performance issues such as open circuits and/or shorts. In some implementations, the errors may be corrected in the first and second correction regions 812 and 816 by modifying a pattern for one or more elements at the reticle edges by adding additional shapes and/or changing the location of edges of an element to be patterned in one or more directions. For example, the edges or boundaries of elements (e.g., trenches) may be moved in the x-direction or y-direction to increase the size of portions of the elements inside the first and second correction regions 812 and 816 relative to the size of portions of the elements outside of the first and second correction regions 812 and 816. Similar to what is described in connection with FIGS. 6A and 6B, the modifications to the elements for the first and second correction regions 812 and 816 may be made to the reticle patterns, and may be translated to differences (e.g., size differences) between portions of actual structures formed inside the first and second correction regions 812 and 816 and outside of the first and second correction regions 812 and 816. A logic operation (LOP) may be performed to generate the compensatory reticle patterns for the first and second correction regions 812 and 816. In some implementations, the first and/or second correction regions 812 and 816 may be used to define a critical device region, such that components are not formed in the first and/or second correction regions 812 and 816, with a critical device region (e.g., a region where components, circuitry, conductive structures, etc. are formed) being outside of the first and/or second correction regions 812 and 816.

The first correction region 812 corresponds to a portion of the semiconductor chip 802 where edges of the first and second exposure regions 804 and 806, and edges of the third and fourth exposure regions 808 and 810, interface with each other. In other words, the first correction region 812 is at a portion of the semiconductor chip 802 where patterning by a first reticle ends, and patterning by a second reticle begins, and where patterning by a third reticle ends and patterning by a fourth reticle begins. In more detail, the first correction region 812 is at and/or adjacent to an interface 814 between the first and second exposure regions 804 and 806, includes a part (e.g., an end portion) of the first exposure region 804, and includes a part (e.g., an end portion) of the second exposure region 806. The first correction region 812 is also at and/or adjacent to an interface 814 between the third and fourth exposure regions 808 and 810, includes a part (e.g., an end portion) of the third exposure region 808, and includes a part (e.g., an end portion) of the fourth exposure region 810. The second correction region 816 corresponds to a portion of the semiconductor chip 802 where edges of the first and third exposure regions 804 and 808, and edges of the second and fourth exposure regions 806 and 810, interface with each other. In other words, the second correction region 816 is at a portion of the semiconductor chip 802 where patterning by a first reticle ends, and patterning by a third reticle begins, and where patterning by a second reticle ends and patterning by a fourth reticle begins. In more detail, the second correction region 816 is at and/or adjacent to an interface 818 between the first and third exposure regions 804 and 808, includes a part (e.g., an end portion) of the first exposure region 804, and includes a part (e.g., an end portion) of the third exposure region 808. The second correction region 816 is also at and/or adjacent to an interface 818 between the second and fourth exposure regions 806 and 810, includes a part (e.g., an end portion) of the second exposure region 806, and includes a part (e.g., an end portion) of the fourth exposure region 810.

As shown by the arrows in FIG. 8, a first exposure operation using a first reticle to form structures (e.g., integrated circuit devices and/or trenches/recesses for metallization structures and/or interconnect structures) in the first exposure region 804 is followed by a second exposure operation using a second reticle to form the structures in the second exposure region 806, which is followed by a third exposure operation using a third reticle to form the structures in the third exposure region 808, which is followed by a fourth exposure operation using a fourth reticle to form the structures in the fourth exposure region 810. Exposure operations using first, second, third, and fourth reticles may be alternately performed for layers of the semiconductor chip 802 until chip fabrication is completed. The use of multiple reticles (e.g., in this case, four reticles) in multiple exposure operations (e.g., in this case, four exposure operations) enables the formation of a large area (e.g., greater than 26×33 mm² (858 mm²)) semiconductor chip 802. The large area semiconductor chip 802 may incorporate various circuit functions that may be needed for HPC functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

As indicated above, FIG. 8 is provided as an example. Other examples may differ from what is described with regard to FIG. 8.

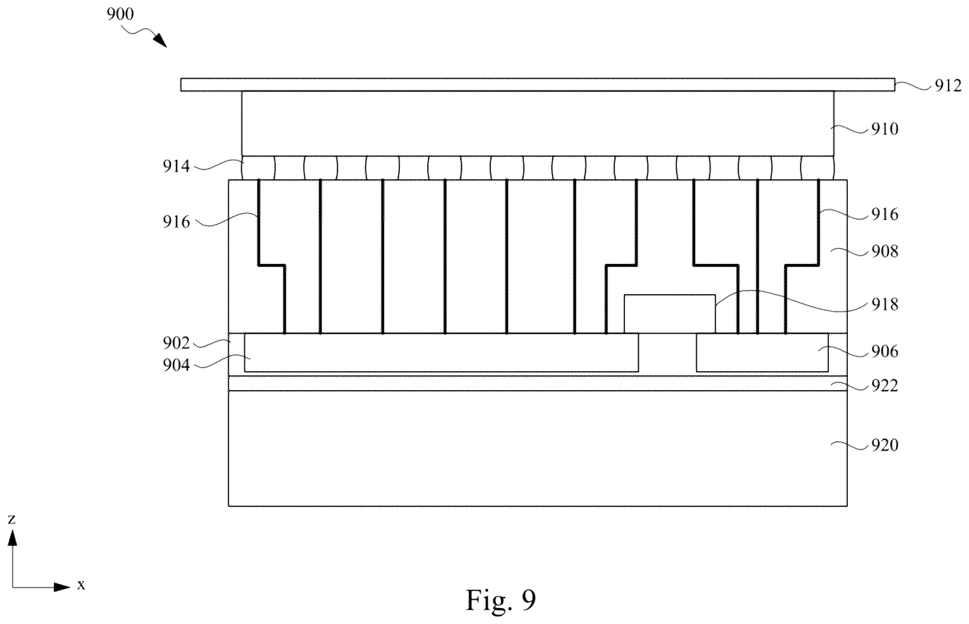

FIG. 9 is a diagram of an example semiconductor device 900. The semiconductor device 900 includes a substrate 902 in which semiconductor chips 904 and 906 are disposed. In some implementations, a molding compound (not shown) may be formed on the substrate 902, and the semiconductor chips 904 and 906 may be disposed in the molding compound such that the molding compound is between the semiconductor chips 904 and 906. The semiconductor chip 904 has a larger area than the semiconductor chip 906. The semiconductor chip 904 may be the same as or similar to the semiconductor chips 202, 702, and 802. For example, the semiconductor chip 904 may include multiple exposure regions including components that were patterned using multiple reticles. In some implementations, the semiconductor chip 906 may be a chip that was formed using a single reticle or a smaller quantity of reticles than those used to form the semiconductor chip 904.

The semiconductor device 900 may include redistribution layers (RDL) 908 formed over the semiconductor chips 904 and 906 in the z-direction. The redistribution layers may include one or more dielectric layers such as, for example, ILD layers and/or ESLs, which are composed of polyimide (PI), benzocyclobutene (BCB) and/or polybenzoxazole (PBO), among other examples. The semiconductor device 900 further includes a power distribution and connectivity layer 910 formed over the RDLs 908 in the z-direction. The power distribution and connectivity layer 910 may include circuits and lines for the receipt and distribution of power and/or signals to portions of the semiconductor device 900, including to functional circuitry of the semiconductor chips 904 and 906. The circuits and lines for the receipt and distribution of power and/or signals may receive power through external connections 912, and may include one or more power rails connected to one or more power delivery networks (PDNs).

Connection structures 914 such as, for example, solder balls, solder bumps, contact pads (e.g., LGA pads), contact pins (e.g., PGA pins), UBM connections, microbumps, BGA balls, C4 bumps, and/or other types of connection structures may be coupled between the power distribution and connectivity layer 910 and the RDL 908 to distribute power and/or signals to conductive structures 916 in the RDL 908. The conductive structures may include, for example, metallization structures and/or interconnect structures formed through one or more of the ILD layers and/or ESLs. A chip-to-chip conductive structure 918 formed through one or more of the ILD layers and/or ESLs electrically couples the semiconductor chip 904 and to the semiconductor chip 906.

A thermal dissipation plate 920 is disposed under the substrate 902 on a backside of the semiconductor device 900. In some implementations, the thermal dissipation plate 920 includes one or more conductive materials such as tungsten (W), cobalt (Co), ruthenium (Ru), titanium (Ti), aluminum (Al), copper (Cu), aluminum copper (AlCu), gold (Au), nickel (Ni), and/or a combination thereof, among other examples of conductive materials. The thermal dissipation plate 920 may function to dissipate heat generated by devices and/or circuitry in the semiconductor chips 904 and/or 906 during operation. The heat dissipation decreases semiconductor chip temperature, which may increase device reliability and performance.

In some implementations, the thermal dissipation plate 920 may be bonded to the substrate 902 using one or more thermal interface materials (TIMs) 922 between the thermal dissipation plate 920 and the substrate 902. The TIMs 922 may facilitate dissipation of heat from the devices and/or circuitry in the semiconductor chips 904 and/or 906. The TIMs 922 may include liquid polymer pastes, wax pads, aluminum pads, graphite pads, silicone pads, tapes, solders, gels, and/or other materials.

As indicated above, FIG. 9 is provided as an example. Other examples may differ from what is described with regard to FIG. 9.

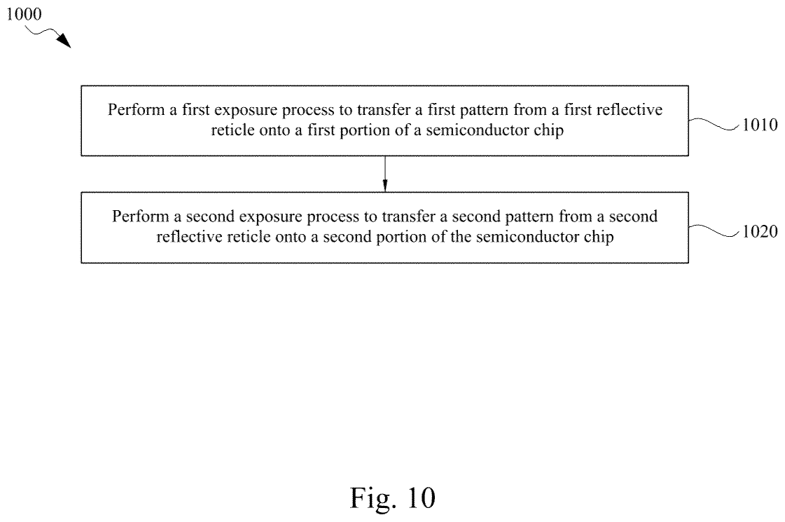

FIG. 10 is a flowchart of an example process 1000 associated with forming a semiconductor device. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include performing a first exposure process to transfer a first pattern from a first reflective reticle onto a first portion of a semiconductor chip (block 1010). For example, one or more semiconductor processing tools may be used to perform a first exposure process to transfer a first pattern from a first reflective reticle (e.g., first reflective reticle 108a) onto a first portion (e.g., first exposure region 206, 706, 804) of a semiconductor chip (e.g., semiconductor chip 202, 702, 802), as described herein.

As further shown in FIG. 10, process 1000 may include performing a second exposure process to transfer a second pattern from a second reflective reticle onto a second portion of the semiconductor chip (block 1020). For example, one or more semiconductor processing tools may be used to perform a second exposure process to transfer a second pattern from a second reflective reticle (e.g., second reflective reticle 108b) onto a second portion (e.g., second exposure region 208, 708, 806) of the semiconductor chip, as described herein. In some implementations, the second portion of the semiconductor chip is laterally adjacent to the first portion of the semiconductor chip.

Process 1000 may include additional implementations, such as any single implementation or any combination of implementations described below and/or in connection with one or more other processes described elsewhere herein.

In a first implementation, performing the first exposure process includes focusing first radiation onto the first reflective reticle to transfer the first pattern onto the first portion of the semiconductor chip, and performing the second exposure process includes focusing second radiation onto the second reflective reticle to transfer the second pattern onto the second portion of the semiconductor chip.

In a second implementation, alone or in combination with the first implementation, the first pattern is for a first part of a conductive structure (e.g., metallization structure 602, 608, and/or interconnect structure 604, 610) disposed in the first portion of the semiconductor chip, and the second pattern is for a second part of the conductive structure disposed in the second portion of the semiconductor chip.

In a third implementation, alone or in combination with one or more of the first and second implementations, the conductive structure includes at least one of a metallization structure (e.g., metallization structure 602, 608) or an interconnect structure (e.g., interconnect structure 604, 610).

In a fourth implementation, alone or in combination with one or more of the first through third implementations, the semiconductor chip includes a proximity correction region (e.g., correction region 404, first correction regions 728, 812) adjacent to an interface (e.g., interface 406, 730, 814) between the first portion of the semiconductor chip and the second portion of the semiconductor chip, where the proximity correction region includes a part of the first portion of the semiconductor chip and a part of the second portion of the semiconductor chip, and where the conductive structure has a larger dimension in the proximity correction region than in a remaining part of the first portion of the semiconductor chip and a remaining part of the second portion of the semiconductor chip.

In a fifth implementation, alone or in combination with one or more of the first through fourth implementations, a device layer (e.g., device layer 222) is divided between the first portion of the semiconductor chip and the second portion of the semiconductor chip.

In a sixth implementation, alone or in combination with one or more of the first through fifth implementations, an interconnect layer (e.g., interconnect layer 224) is divided between the first portion of the semiconductor chip and the second portion of the semiconductor chip.

In a seventh implementation, alone or in combination with one or more of the first through sixth implementations, process 1000 includes forming an alignment mark (e.g., in-chip alignment mark 504) at an interface between the first portion of the semiconductor chip and the second portion of the semiconductor chip.

In an eighth implementation, alone or in combination with one or more of the first through seventh implementations, a first part of the alignment mark is in the first portion of the semiconductor chip and a second part of the alignment mark is in the second portion of the semiconductor chip.

In a ninth implementation, alone or in combination with one or more of the first through eighth implementations, process 1000 includes performing a third exposure process to transfer a third pattern from a third reflective reticle onto a third portion (e.g., third exposure region 710, 808) of the semiconductor chip, where the third portion of the semiconductor chip is adjacent to one of the first portion of the semiconductor chip or the second portion of the semiconductor chip.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

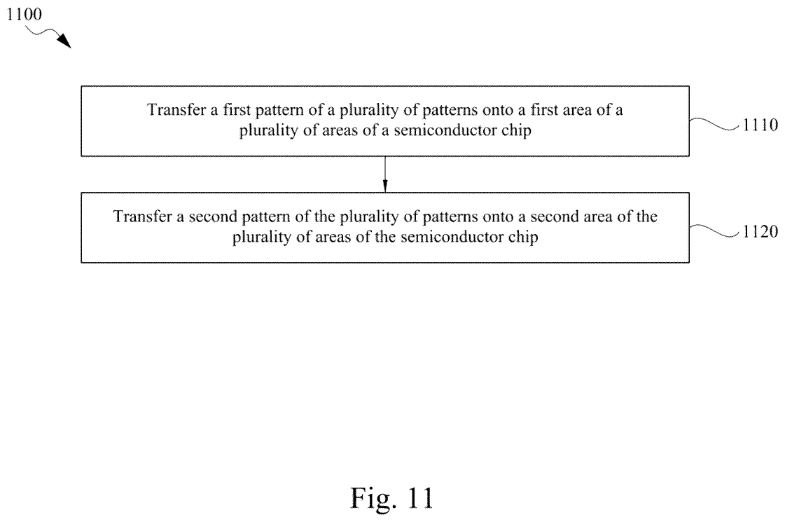

FIG. 11 is a flowchart of an example process 1100 associated with forming a semiconductor device. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include transferring a first pattern of a plurality of patterns onto a first area of a plurality of areas of a semiconductor chip (block 1110). For example, one or more semiconductor processing tools may be used to transfer a first pattern of a plurality of patterns onto a first area (e.g., first exposure region 206, 706, 804) of a plurality of areas of a semiconductor chip (e.g., semiconductor chip 202, 702, 802), as described herein. In some implementations, transferring of the first pattern is performed using a first reticle (e.g., first reflective reticle 108a).

As further shown in FIG. 11, process 1100 may include transferring a second pattern of the plurality of patterns onto a second area of the plurality of areas of the semiconductor chip (block 1120). For example, one or more semiconductor processing tools may be used to transfer a second pattern of the plurality of patterns onto a second area (e.g., second exposure region 208, 708, 806) of the plurality of areas of the semiconductor chip, as described herein. In some implementations, transferring of the second pattern is performed using a second reticle (e.g., second reflective reticle 108b). In some implementations, the second area abuts the first area.

Process 1100 may include additional implementations, such as any single implementation or any combination of implementations described below and/or in connection with one or more other processes described elsewhere herein.

In a first implementation, process 1100 includes transferring a third pattern of the plurality of patterns onto a third area (e.g., third exposure region 710) of the plurality of areas of the semiconductor chip, where the third area abuts the second area, where the first area, the second area, and the third area are sequentially arranged along a same direction (e.g., x-direction), and where transferring of the first pattern, the second pattern, and the third pattern are sequentially performed.

In a second implementation, alone or in combination with the first implementation, process 1100 includes transferring a third pattern of the plurality of patterns onto a third area (e.g., third exposure region 808) of the plurality of areas of the semiconductor chip, where the third area abuts the first area, where the first area and the second area are arranged along a first direction (e.g., x-direction), and where the first area and the third area are arranged along a second direction (e.g., y-direction) perpendicular to the first direction.

In a third implementation, alone or in combination with one or more of the first and second implementations, process 1100 includes transferring a fourth pattern of the plurality of patterns onto a fourth area (e.g., fourth exposure region 810) of the plurality of areas of the semiconductor chip, where the fourth area abuts the third area and the second area, where the third area and the fourth area are arranged along the first direction, and where the second area and the fourth area are arranged along the second direction.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, in order to address reticle-based chip size limitations, a semiconductor chip includes a plurality of exposure regions which are sequentially patterned by different reticles. For example, two or more reticles may be used to respectively pattern different portions of the semiconductor chip, resulting in a semiconductor chip with increased area in comparison to semiconductor chips manufactured with a single reticle. As a result, the semiconductor chip can incorporate various circuit functions that may be needed for HPC functions without chip size limitations. Accordingly, a single large area semiconductor chip with internal connections between different functional components may be used in place of multiple smaller area semiconductor chips that are spaced apart from each other and externally connected to each other. As a result of the elimination of the external connections and spacing between multiple semiconductor chips, HPC performance may be increased and/or failure risk may be decreased, leading to an increase in device reliability.

As described in greater detail above, some implementations described herein provide a method. The method includes performing a first exposure process to transfer a first pattern from a first reflective reticle onto a first portion of a semiconductor chip. The method includes performing a second exposure process to transfer a second pattern from a second reflective reticle onto a second portion of the semiconductor chip, where the second portion of the semiconductor chip is laterally adjacent to the first portion of the semiconductor chip.

As described in greater detail above, some implementations described herein provide a semiconductor device. The semiconductor device includes a semiconductor chip. The semiconductor chip includes a first exposure region, a second exposure region bordering the first exposure region, and a correction region at an interface between the first exposure region and the second exposure region. The correction region includes an end portion of the first exposure region and an end portion of the second exposure region, where the end portion of the first exposure region is adjacent to the end portion of the second exposure region.

As described in greater detail above, some implementations described herein provide a method. The method includes transferring a first pattern of a plurality of patterns onto a first area of a plurality of areas of a semiconductor chip, where transferring of the first pattern is performed using a first reticle. The method includes transferring a second pattern of the plurality of patterns onto a second area of the plurality of areas of the semiconductor chip, where transferring of the second pattern is performed using a second reticle, and where the second area abuts the first area.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a first exposure process to transfer a first pattern from a first reflective reticle onto a first portion of a semiconductor chip; and
performing a second exposure process to transfer a second pattern from a second reflective reticle onto a second portion of the semiconductor chip,
wherein the second portion of the semiconductor chip is laterally adjacent to the first portion of the semiconductor chip.

2. The method of claim 1, wherein performing the first exposure process comprises focusing first radiation onto the first reflective reticle to transfer the first pattern onto the first portion of the semiconductor chip, and
wherein performing the second exposure process comprises focusing second radiation onto the second reflective reticle to transfer the second pattern onto the second portion of the semiconductor chip.

3. The method of claim 1, wherein the first pattern is for a first part of a conductive structure disposed in the first portion of the semiconductor chip, and
wherein the second pattern is for a second part of the conductive structure disposed in the second portion of the semiconductor chip.

4. The method of claim 3, wherein the conductive structure comprises at least one of a metallization structure or an interconnect structure.

5. The method of claim 3, wherein the semiconductor chip comprises a proximity correction region adjacent to an interface between the first portion of the semiconductor chip and the second portion of the semiconductor chip,
wherein the proximity correction region includes a part of the first portion of the semiconductor chip and a part of the second portion of the semiconductor chip, and
wherein the conductive structure has a larger dimension in the proximity correction region than in a remaining part of the first portion of the semiconductor chip and a remaining part of the second portion of the semiconductor chip.

6. The method of claim 1, wherein a device layer is divided between the first portion of the semiconductor chip and the second portion of the semiconductor chip.

7. The method of claim 1, wherein an interconnect layer is divided between the first portion of the semiconductor chip and the second portion of the semiconductor chip.

8. The method of claim 1, further comprising forming an alignment mark at an interface between the first portion of the semiconductor chip and the second portion of the semiconductor chip.

9. The method of claim 8, wherein a first part of the alignment mark is in the first portion of the semiconductor chip and a second part of the alignment mark is in the second portion of the semiconductor chip.

10. The method of claim 1, further comprising performing a third exposure process to transfer a third pattern from a third reflective reticle onto a third portion of the semiconductor chip,
wherein the third portion of the semiconductor chip is adjacent to one of the first portion of the semiconductor chip or the second portion of the semiconductor chip.

11. A semiconductor device, comprising:
a semiconductor chip,
wherein the semiconductor chip comprises:
a first exposure region;
a second exposure region bordering the first exposure region; and
a correction region at an interface between the first exposure region and the second exposure region,
wherein the correction region includes an end portion of the first exposure region and an end portion of the second exposure region, and
wherein the end portion of the first exposure region is adjacent to the end portion of the second exposure region.

12. The semiconductor device of claim 11, wherein the semiconductor chip further comprises a first portion of a structure disposed inside the correction region and a second portion of the structure disposed outside of the correction region,
wherein the first portion is contiguous with the second portion, and
wherein a dimension of the first portion along an axis is greater than a dimension of the second portion along the axis.

13. The semiconductor device of claim 11, wherein an area of the semiconductor chip is greater than approximately 858 mm².

14. The semiconductor device of claim 11, further comprising an additional semiconductor chip,
wherein an area of the additional semiconductor chip is less than an area of the semiconductor chip.

15. The semiconductor device of claim 11, wherein the semiconductor chip further comprises a third exposure region bordering one of the first exposure region or the second exposure region.

16. The semiconductor device of claim 11, wherein the semiconductor chip further comprises:
a third exposure region bordering the first exposure region; and
a fourth exposure region bordering the third exposure region and the second exposure region.

17. A method, comprising:
transferring a first pattern of a plurality of patterns onto a first area of a plurality of areas of a semiconductor chip,
wherein transferring of the first pattern is performed using a first reticle; and
transferring a second pattern of the plurality of patterns onto a second area of the plurality of areas of the semiconductor chip,
wherein transferring of the second pattern is performed using a second reticle, and
wherein the second area abuts the first area.

18. The method of claim 17, further comprising transferring a third pattern of the plurality of patterns onto a third area of the plurality of areas of the semiconductor chip,
wherein the third area abuts the second area,
wherein the first area, the second area, and the third area are sequentially arranged along a same direction, and
wherein transferring of the first pattern, the second pattern, and the third pattern are sequentially performed.

19. The method of claim 17, further comprising transferring a third pattern of the plurality of patterns onto a third area of the plurality of areas of the semiconductor chip,
wherein the third area abuts the first area,
wherein the first area and the second area are arranged along a first direction, and
wherein the first area and the third area are arranged along a second direction perpendicular to the first direction.

20. The method of claim 19, further comprising transferring a fourth pattern of the plurality of patterns onto a fourth area of the plurality of areas of the semiconductor chip,
wherein the fourth area abuts the third area and the second area,
wherein the third area and the fourth area are arranged along the first direction, and
wherein the second area and the fourth area are arranged along the second direction.
